(19) United States
(12) Patent Application Publication
(10) Pub. No.: US 2025/0258438 A1
(43) Pub. Date: Aug. 14, 2025

(54) LASER PROCESSING SYSTEM, LASER PROCESSING METHOD, AND METHOD FOR MANUFACTURING ELECTRONIC DEVICE

(71) Applicant: Gigaphoton Inc., Tochigi (JP)

(72) Inventors: Akira SUWA, Oyama-shi (JP); Kouji KAKIZAKI, Oyama-shi (JP); Yasufumi KAWASUJI, Oyama-shi (JP); Osamu WAKABAYASHI, Oyama-shi (JP)

(73) Assignee: Gigaphoton Inc., Tochigi (JP)

(21) Appl. No.: 19/196,072

(22) Filed: May 1, 2025

Related U.S. Application Data
(63) Continuation of application No. PCT/JP2022/044993, filed on Dec. 6, 2022.

(51) Int. Cl. G03F 7/00; G02B 27/42; H01L 21/48

(52) U.S. Cl. CPC G03F 7/70558; G02B 27/4222; G03F 7/70025; G03F 7/70041; G03F 7/70108; G03F 7/70158; G03F 7/70316; G03F 7/70333; G03F 7/70504; G03F 7/70525; G03F 7/70591; H01L 21/4846

(57) ABSTRACT

A laser processing system includes a laser apparatus configured to output pulse laser light; a diffractive optical element configured to divide the pulse laser light into multiple first diffracted luminous fluxes to be radiated to multiple processing points on a workpiece, and multiple second diffracted luminous fluxes to be radiated to multiple non-processing points on the workpiece; a focusing optical system configured to focus each of the first and second diffracted luminous fluxes at the workpiece; an adjustment mechanism configured to adjust pulse energy of the pulse laser light incident on the diffractive optical element; and a processor configured to control the adjustment mechanism based on parameters including a processing threshold Fth of a fluence for processing the workpiece in such a way that a fluence F_{OK}m of the first diffracted luminous fluxes at a surface of the workpiece is greater than the processing threshold Fth, and a fluence F_{NG}m of the second diffracted luminous fluxes at the surface of the workpiece is smaller than or equal to the processing threshold Fth.

### CROSS-REFERENCE TO RELATED APPLICATIONS

The present application is a continuation application of International Application No. PCT/JP2022/044993, filed on Dec. 6, 2022, the entire contents of which are hereby incorporated by reference.

### BACKGROUND

### 1. Technical Field

The present disclosure relates to a laser processing system, a laser processing method, and a method for manufacturing an electronic device.

### 2. Related Art

In recent years, a semiconductor exposure apparatus is required to improve the resolution thereof as semiconductor integrated circuits are increasingly miniaturized and highly integrated. To this end, reduction in the wavelength of light emitted from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

Excimer laser light output from a KrF excimer laser apparatus and excimer laser light output from an ArF excimer laser apparatus each have a pulse width of a few tens of nanoseconds, have short wavelengths of about 248 nm and about 193 nm, respectively, and can therefore be used for direct processing of polymer materials, glass materials, and the like.

The excimer laser light having photon energy higher than the chemical binding energy of a polymer material can unbind the chemically bonded molecules that form the polymer material. Non-thermal processing can therefore be performed on the polymer material by using the excimer laser light, and it is known that the non-thermal processing provides an excellent processed shape.

Glass, ceramic, and other materials absorb the excimer laser light by a large amount, and it is therefore known that the excimer laser light can process a material difficult to process with a visible or infrared laser light.

### CITATION LIST

### Patent Literature

PTL 1: U.S. Patent Application Publication No. 2004/0150887
PTL 2: U.S. Patent Application Publication No. 2006/0289412

### SUMMARY

A laser processing system according to an aspect of the present disclosure includes a laser apparatus configured to output pulse laser light; a diffractive optical element configured to divide the pulse laser light into multiple first diffracted luminous fluxes to be radiated to multiple processing points on a workpiece, and multiple second diffracted luminous fluxes to be radiated to multiple non-processing points on the workpiece; a focusing optical system configured to focus each of the first and second diffracted luminous fluxes at the workpiece; an adjustment mechanism configured to adjust pulse energy of the pulse laser light incident on the diffractive optical element; and a processor configured to control the adjustment mechanism based on parameters including a processing threshold Fth of a fluence for processing the workpiece in such a way that a fluence F_{OK}m of the first diffracted luminous fluxes at a surface of the workpiece is greater than the processing threshold Fth, and a fluence F_{NG}m of the second diffracted luminous fluxes at the surface of the workpiece is smaller than or equal to the processing threshold Fth.

A laser processing method according to another aspect of the present disclosure includes: causing a laser apparatus to output pulse laser light; causing a diffractive optical element to divide the pulse laser light into multiple first diffracted luminous fluxes radiated to multiple processing points on a workpiece, and multiple second diffracted luminous fluxes radiated to multiple non-processing points on the workpiece; controlling an adjustment mechanism configured to adjust pulse energy of the pulse laser light based on parameters including a processing threshold Fth of a fluence for processing the workpiece in such a way that a fluence F_{OK}m of the first diffracted luminous fluxes at a surface of the workpiece is greater than the processing threshold Fth, and a fluence F_{NG}m of the second diffracted luminous fluxes at the surface of the workpiece is smaller than or equal to the processing threshold Fth; and causing a focusing optical system to focus each of the first and second diffracted luminous fluxes at the workpiece.

A method for manufacturing an electronic device according to another aspect of the present disclosure includes processing an interposer substrate with laser light by using a laser processing system to produce an interposer; coupling the interposer to an integrated circuit chip to electrically connect the interposer and the integrated circuit chip to each other; and coupling the interposer to a circuit substrate to electrically connect the interposer and the circuit substrate to each other, the laser processing system including a laser apparatus configured to output pulse laser light, a diffractive optical element configured to divide the pulse laser light into multiple first diffracted luminous fluxes radiated to multiple processing points on a workpiece, and multiple second diffracted luminous fluxes radiated to multiple non-processing points on the workpiece, a focusing optical system configured to focus each of the first and second diffracted luminous fluxes at the workpiece; an adjustment mechanism configured to adjust pulse energy of the pulse laser light incident on the diffractive optical element, and a processor configured to control the adjustment mechanism based on parameters including a processing threshold Fth of a fluence for processing the workpiece in such a way that a fluence F_{OK}m of the first diffracted luminous fluxes at a surface of the workpiece is greater than the processing threshold Fth, and a fluence F_{NG}m of the second diffracted luminous fluxes at the surface of the workpiece is smaller than or equal to the processing threshold Fth.

### BRIEF DESCRIPTION OF DRAWINGS

Some embodiments of the present disclosure will be described below only by way of example with reference to the accompanying drawings.

FIG. 1 schematically shows the configuration of a laser processing system according to Comparative Example.

FIG. 2 is a cross-sectional view of a diffraction grating that serves as a base of a diffractive optical element.

FIG. 3 shows a combination of multiple diffraction gratings to illustrate the principle of the diffractive optical element.

FIG. 4 shows an example of a designed diffractive optical element.

FIG. 5 shows an example of a pattern of diffracted luminous fluxes radiated from the diffractive optical element onto a workpiece.

FIG. 6 is a flowchart showing laser processing processes in Comparative Example.

FIG. 7 is a flowchart showing the process of reading information on the laser processing system in detail.

FIG. 8 is a flowchart showing the process of reading information on the workpiece in detail.

FIG. 9 is a graph showing an example of the definition of a processing threshold.

FIG. 10 is a flowchart showing the process of reading information on the diffractive optical element in detail.

FIG. 11 is a flowchart showing the process of determining a target fluence at a processing point in detail.

FIG. 12 is a flowchart showing details of the process of determining the number of radiated pulses and a repetition frequency in single laser processing.

FIG. 13 is a flowchart showing details of the process for adjusting the laser processing system based on the target fluence.

FIG. 14 is a flowchart showing the process of performing the laser processing in detail.

FIG. 15 shows another example of the pattern of the diffracted luminous fluxes radiated from the diffractive optical element onto the workpiece.

FIG. 16 is a bar graph showing a problem with Comparative Example.

FIG. 17 is a bar graph showing an example of the result of control in a first embodiment.

FIG. 18 is a bar graph showing an example of a target fluence of first diffracted luminous fluxes that is set in the first embodiment.

FIG. 19 is a flowchart showing laser processing processes in the first embodiment.

FIG. 20 is a flowchart showing the process of reading information on the diffractive optical element in detail.

FIG. 21 is a flowchart showing the process of determining the target fluence at a processing point in detail.

FIG. 22 is a flowchart showing details of the process of determining the number of radiated pulses and the repetition frequency in the single laser processing.

FIG. 23 is a flowchart showing details of the process of adjusting the laser processing system based on the target fluence.

FIG. 24 is a bar graph showing an example of the result of control in a second embodiment.

FIG. 25 is a bar graph showing an example of the target fluence of a first minimum diffracted luminous flux that is set in the second embodiment.

FIG. 26 schematically shows the configuration of a measurement system that measures information on the diffractive optical element in the second embodiment.

FIG. 27 is a flowchart showing the process of measuring optical intensities in the second embodiment.

FIG. 28 is a flowchart showing laser processing processes in the second embodiment.

FIG. 29 is a flowchart showing the process of reading information on the diffractive optical element in detail.

FIG. 30 is a flowchart showing the process of determining the target fluence of the first minimum diffracted luminous flux in detail.

FIG. 31 is a flowchart showing details of the process of determining the number of radiated pulses and the repetition frequency in the single laser processing.

FIG. 32 is a flowchart showing details of the process of adjusting the laser processing system based on the target fluence.

FIG. 33 is a bar graph showing an example of the result of control in a variation of the second embodiment.

FIG. 34 is a bar graph showing an example of the target fluence of the first minimum diffracted luminous flux that is set in the variation of the second embodiment.

FIG. 35 is a flowchart showing laser processing processes in the variation of the second embodiment.

FIG. 36 is a flowchart showing the process of reading information on the laser processing system in detail.

FIG. 37 is a flowchart showing the process of determining the target fluence of the first minimum diffracted luminous flux in detail.

FIG. 38 is a bar graph showing an example of the result of control in a third embodiment.

FIG. 39 is a graph showing an example of the definition of a fluence upper limit.

FIG. 40 is a bar graph showing an example of the target fluence of the first minimum diffracted luminous flux that is set in the third embodiment.

FIG. 41 is a bar graph showing another example of the target fluence of the first minimum diffracted luminous flux that is set in the third embodiment.

FIG. 42 is a flowchart showing the process of measuring the optical intensities in the third embodiment.

FIG. 43 is a flowchart showing laser processing processes in the third embodiment.

FIG. 44 is a flowchart showing the process of reading information on the workpiece in detail.

FIG. 45 is a flowchart showing the process of reading information on the diffractive optical element in detail.

FIG. 46 is a flowchart showing the process of determining the target fluence of the first minimum diffracted luminous flux in detail.

FIG. 47 is a bar graph showing an example of the result of control in a variation of the third embodiment.

FIG. 48 is a bar graph showing an example of the target fluence of the first minimum diffracted luminous flux that is set in the variation of the third embodiment.

FIG. 49 is a flowchart showing laser processing processes in the variation of the third embodiment.

FIG. 50 is a flowchart showing the process of determining the target fluence of the first minimum diffracted luminous flux in detail.

FIG. 51 diagrammatically shows the configuration of an electronic device.

FIG. 52 is a flowchart showing a method for manufacturing an electronic device.

### DETAILED DESCRIPTION

### <Contents>

1. Laser processing system according to Comparative Example
1.1 Configuration
1.1.1 Configuration of laser apparatus 1
1.1.2 Configuration of laser processing apparatus 5
1.1.3 Configuration of data managing server 93
1.2 Operation
1.2.1 Operation of laser apparatus 1
1.2.2 Operation of laser processing apparatus 5
1.3 Diffractive optical element 63
1.4 Processes carried out by laser processing processor 53
1.4.1 Read laser processing system information
1.4.2 Read workpiece information
1.4.3 Read diffractive optical element information
1.4.4 Determine target fluence
1.4.5 Determine number of radiated pulses Nm and repetition frequency f
1.4.6 Adjust laser processing system
1.4.7 Laser processing
1.5 Problems with Comparative Example
2. Laser processing system in which target fluence is so set that fluence of second diffracted luminous fluxes is smaller than or equal to processing threshold Fth
2.1 Concept
2.1.1 Fluences of first and second diffracted luminous fluxes
2.1.2 Set target fluence F_{OK}mt
2.1.2.1 Lower limit of target fluence F_{OK}mt
2.1.2.2 Upper limit of target fluence F_{OK}mt
2.1.2.3 Range of target fluence F_{OK}mt
2.2 Configuration of laser processing system
2.3 Processes carried out by laser processing processor 53
2.3.1 Read diffractive optical element information
2.3.2 Determine target fluence
2.3.3 Determine number of radiated pulses Nm and repetition frequency f
2.3.4 Adjust laser processing system
2.4 Effects
3. Laser processing system in consideration of variation in fluence between first diffracted luminous fluxes and between second diffracted luminous fluxes
3.1 Concept
3.1.1 Fluences of first and second diffracted luminous fluxes
3.1.2 Set target fluence F_{OK}mt
3.1.2.1 Lower limit of target fluence F_{OK}mt
3.1.2.2 Upper limit of target fluence F_{OK}mt
3.1.2.3 Range of target fluence F_{OK}mt
3.2 Configuration of laser processing system
3.3 Measurement of diffractive optical element information
3.4 Processes carried out by laser processing processor 53
3.4.1 Read diffractive optical element information
3.4.2 Determine target fluence
3.4.3 Determine number of radiated pulses Nm and repetition frequency f
3.4.4 Adjust laser processing system
3.5 Effects
4. Laser processing system in consideration of variation in pulse energy of pulse laser light output from laser apparatus
4.1 Concept
4.1.1 Fluences of first and second diffracted luminous fluxes
4.1.2 Set target fluence F_{OK}mint
4.1.2.1 Lower limit of target fluence F_{OK}mint
4.1.2.2 Upper limit of target fluence F_{OK}mint
4.1.2.3 Range of target fluence F_{OK}mint
4.2 Configuration of laser processing system
4.3 Processes carried out by laser processing processor 53
4.3.1 Read laser processing system information
4.3.2 Determine target fluence
4.4 Effects
5. Laser processing system in consideration of fluence upper limit
5.1 Concept
5.1.1 Fluences of first and second diffracted luminous fluxes
5.1.2 Set target fluence F_{OK}mint
5.1.2.1 Lower limit of target fluence F_{OK}mint
5.1.2.2 Upper limit (1) of target fluence F_{OK}mint
5.1.2.3 Upper limit (2) of target fluence F_{OK}mint
5.1.2.4 Range of target fluence F_{OK}mint
5.2 Configuration of laser processing system
5.3 Measure diffractive optical element information
5.4 Processes carried out by laser processing processor 53
5.4.1 Read workpiece information
5.4.2 Read diffractive optical element information
5.4.3 Determine target fluence
5.5 Effects
6. Laser processing system in consideration of fluence upper limit and variation of pulse energy of pulse laser light output from laser apparatus
6.1 Concept
6.1.1 Fluences of first and second diffracted luminous fluxes
6.1.2 Set target fluence F_{OK}mint
6.1.2.1 Lower limit of target fluence F_{OK}mint
6.1.2.2 Upper limit (1) of target fluence F_{OK}mint
6.1.2.3 Upper limit (2) of target fluence F_{OK}mint
6.1.2.4 Range of target fluence F_{OK}mint
6.2 Configuration of laser processing system
6.3 Processes carried out by laser processing processor 53
6.4 Effects
7. Others
7.1 Configuration of electronic device
7.2 Method for manufacturing electronic device
7.3 Supplements

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. It is noted that the same element has the same reference character, and no redundant description of the same element will be made.

### 1. Laser Processing System According to Comparative Example

### 1.1 Configuration

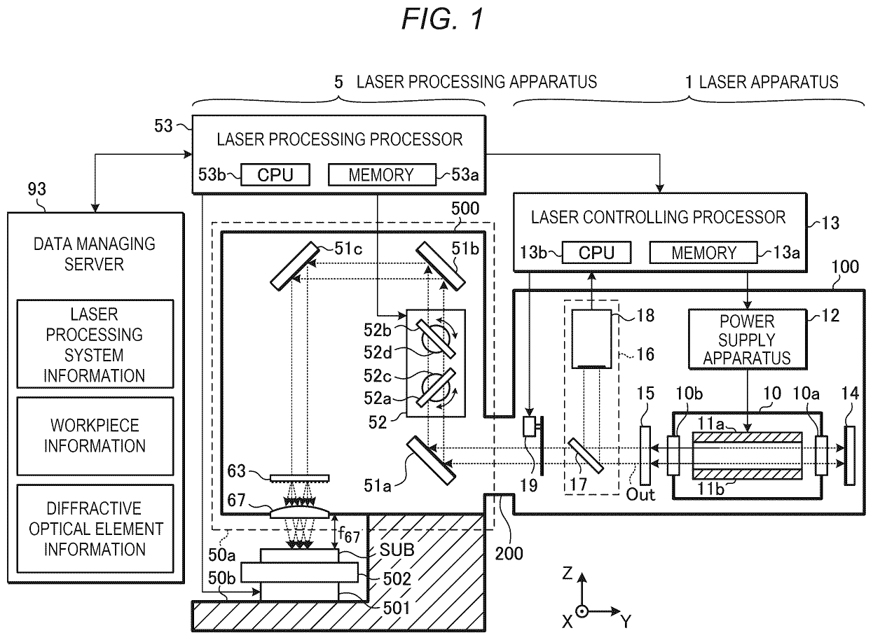

FIG. 1 schematically shows the configuration of a laser processing system according to Comparative Example. Comparative Example of the present disclosure is an aspect that the applicant is aware of as known only by the applicant, and is not a publicly known example that the applicant is self-aware of. The laser processing system includes a laser apparatus 1, a laser processing apparatus 5, and a data managing server 93.

### 1.1.1 Configuration of Laser Apparatus 1

The laser apparatus 1 is a gas laser apparatus that outputs ultraviolet pulse laser light Out. The laser apparatus 1 includes a laser chamber 10, a power supply apparatus 12, a rear mirror 14, an output coupling mirror 15, a monitor module 16, and a shutter 19. These elements are housed in a first enclosure 100. The rear mirror 14 and the output coupling mirror 15 form an optical resonator.

The laser chamber 10 is disposed in the optical path of the optical resonator. The laser chamber 10 is provided with windows 10a and 10b. The laser chamber 10 accommodates a pair of discharge electrodes 11a and 11b. The laser chamber 10 is filled with a laser gas containing, for example, an argon or krypton gas as a rare gas, a fluorine gas as a halogen gas, and a neon gas as a buffer gas.

The rear mirror 14 is configured with a highly reflective mirror, and the output coupling mirror 15 is configured with a partially reflective mirror. The pulse laser light Out is output via the output coupling mirror 15.

The monitor module 16 includes a beam splitter 17 and a photosensor 18. The beam splitter 17 is located in the optical path of the pulse laser light Out output via the output coupling mirror 15. The photosensor 18 is located in the optical path of the pulse laser light Out reflected off the beam splitter 17.

The shutter 19 is located in the optical path of the pulse laser light Out having passed through the beam splitter 17. The shutter 19 is configured to be capable of performing switching between the state in which the pulse laser light Out passes to the laser processing apparatus 5 and the state in which the pulse laser light Out is blocked and vice versa.

The laser apparatus 1 further includes a laser control processor 13. The laser control processor 13 is a processing apparatus including a memory 13a, which stores a control program, and a CPU (central processing unit) 13b, which executes the control program. The laser control processor 13 is particularly configured or programmed to carry out various processes described in the present disclosure.

### 1.1.2 Configuration of Laser Processing Apparatus 5

The laser processing apparatus 5 includes a radiation optical system 50a, a frame 50b, an XYZ stage 501, and a laser processing processor 53. The radiation optical system 50a and the XYZ stage 501 are fixed to the frame 50b. A workpiece SUB is supported by a table 502 of the XYZ stage 501.

In FIG. 1, the X and Y directions orthogonal to each other are directions parallel to the surface of the workpiece SUB. The Z direction is the direction perpendicular to the surface of the workpiece SUB and parallel to the traveling direction of the pulse laser light Out incident on the surface of the workpiece SUB.

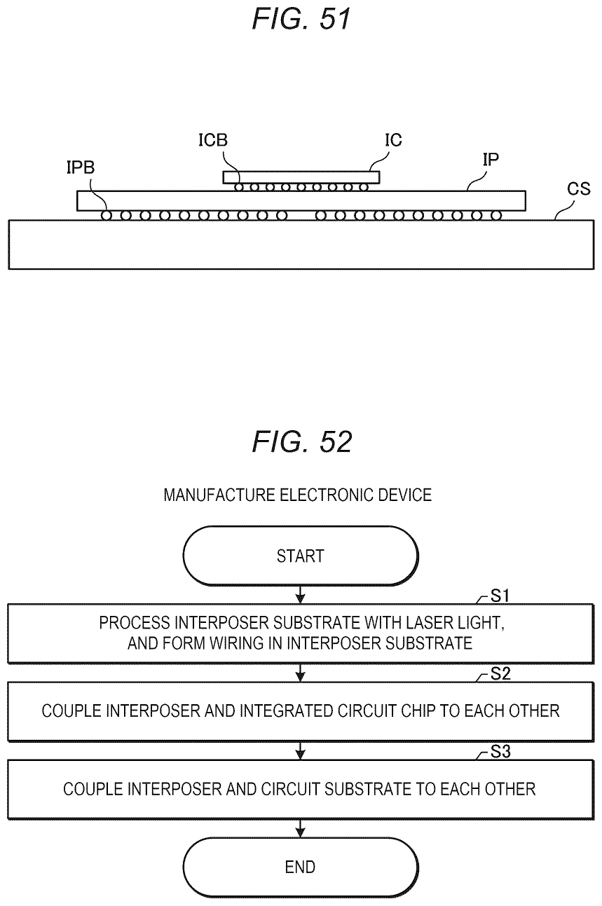

The workpiece SUB is, for example, an interposer substrate used to manufacture an interposer IP, which relays an integrated circuit chip IC and a circuit substrate CS, which will be described later with reference to FIG. 51, to each other. The interposer substrate is made, for example, of an electrically insulating material such as a polymer material, a glass material, a silicon single crystal, or a ceramic material. The workpiece SUB is not limited to the interposer substrate, and may be a substrate having a laser processed metallic film formed thereon.

The radiation optical system 50a includes highly reflective mirrors 51a, 51b, and 51c, an attenuator 52, a diffractive optical element 63, and a focusing optical system 67. The highly reflective mirrors 51a, 51b, and 51c, the attenuator 52, and the diffractive optical element 63 are housed in a second enclosure 500. The focusing optical system 67 also serves as a window of the second enclosure 500. The second enclosure 500 is connected to the first enclosure 100 via an optical path tube 200. The pulse laser light Out output from the laser apparatus 1 passes through the interior of the optical path tube 200 and enters the second enclosure 500.

The highly reflective mirror 51a is located in the optical path of the pulse laser light Out having passed through the interior of the optical path tube 200. The attenuator 52 is located in the optical path of the pulse laser light Out reflected off the highly reflective mirror 51a. The attenuator 52 includes two partially reflective mirrors 52a and 52b and rotary stages 52c and 52d. The rotary stages 52c and 52d are configured to be capable of changing transmittance Ta of the attenuator 52 by changing the angles of incidence of the pulse laser light Out incident on the partially reflective mirrors 52a and 52b, respectively.

The highly reflective mirror 51b is located in the optical path of the pulse laser light Out having passed through the attenuator 52, and the highly reflective mirror 51c is located in the optical path of the pulse laser light Out reflected off the highly reflective mirror 51b.

The diffractive optical element 63 is located in the optical path of the pulse laser light Out reflected off the highly reflective mirror 51c. The diffractive optical element 63 has multiple protrusions and recesses at a surface thereof, and is configured to diffract the pulse laser light Out having passed therethrough to divide the pulse laser light Out into multiple diffracted luminous fluxes.

The focusing optical system 67 is located in the optical path of the pulse laser light Out having passed through the diffractive optical element 63. The focusing optical system 67 focuses each of the diffracted luminous fluxes, into which the pulse laser light Out has been divided by the diffractive optical element 63, at the workpiece SUB. The focusing optical system 67 has a focal length f₆₇. The focusing optical system 67 is desirably configured with an Fθ lens so that the diffracted luminous fluxes, into which the pulse laser light Out has been divided, are focused at the same surface.

The laser processing processor 53 is a processing apparatus including a memory 53a, which stores a control program, and a CPU 53b, which executes the control program. The laser processing processor 53 corresponds to the processor in the present disclosure. The laser processing processor 53 is particularly configured or programmed to carry out various processes described in the present disclosure.

### 1.1.3 Configuration of Data Managing Server 93

The data managing server 93 is a data server that manages laser processing system information, workpiece information, and diffractive optical element information. The laser processing processor 53 can access the data managing server 93 to read the information.

### 1.2 Operation

### 1.2.1 Operation of Laser Apparatus 1

In the laser apparatus 1, the laser control processor 13 receives data on target pulse energy Et and a trigger signal from the laser processing processor 53. The laser control processor 13 sets a voltage provided by the power supply apparatus 12 based on the target pulse energy Et and forwards the trigger signal to the power supply apparatus 12.

Upon receiving the trigger signal from the laser control processor 13, the power supply apparatus 12 generates a pulse-shaped high voltage and applies the high voltage to the space between the discharge electrodes 11a and 11b.

When the high voltage is applied to the space between the discharge electrodes 11a and 11b, discharge occurs between the discharge electrodes 11a and 11b. The energy of the discharge excites the laser gas in the laser chamber 10, and the excited laser gas transitions to a high energy level. Thereafter, when the excited laser gas transitions to a low energy level, the laser gas emits light having a wavelength according to the difference between the energy levels.

The light generated in the laser chamber 10 exits out of the laser chamber 10 via the windows 10a and 10b. The light having exited via the window 10a of the laser chamber 10 is reflected off the rear mirror 14 at high reflectance and returns into the laser chamber 10.

The output coupling mirror 15 transmits and outputs part of the light having exited via the window 10b of the laser chamber 10, and reflects the other part of the light back into the laser chamber 10.

The light having exited out of the laser chamber 10 thus travels back and forth between the rear mirror 14 and the output coupling mirror 15 and is amplified whenever passing through the discharge space between the discharge electrodes 11a and 11b. The pulse laser light Out thus generated through the laser oscillation is output via the output coupling mirror 15.

The monitor module 16 detects the pulse energy of the pulse laser light Out output via the output coupling mirror 15. The monitor module 16 transmits data on the detected pulse energy to the laser control processor 13.

The laser control processor 13 performs feedback control on the voltage set in the power supply apparatus 12 based on the data on the pulse energy received from the monitor module 16 and the data on the target pulse energy Et received from the laser processing processor 53.

### 1.2.2 Operation of Laser Processing Apparatus 5

The XYZ stage 501 is so adjusted that the workpiece SUB is located at a position separate from the focusing optical system 67 by the focal length f₆₇.

The pulse laser light Out output from the laser apparatus 1 passes through the interior of the optical path tube 200 and enters the laser processing apparatus 5. The pulse laser light Out is reflected off the highly reflective mirror 51a and passes through the attenuator 52, and is then sequentially reflected off the highly reflective mirrors 51b and 51c. The laser processing processor 53 sets a target value of the transmittance Ta of the attenuator 52, and controls the rotary stages 52c and 52d based on the target value.

The pulse laser light Out reflected off the highly reflective mirror 51c is divided into the multiple diffracted luminous fluxes by the diffractive optical element 63, and the diffracted luminous fluxes are each focused at the surface of the workpiece SUB by the focusing optical system 67. When the workpiece SUB is irradiated with the diffracted luminous fluxes, into which the pulse laser light Out has been divided, the workpiece SUB is subjected to ablation and laser processing.

### 1.3 Diffractive Optical Element 63

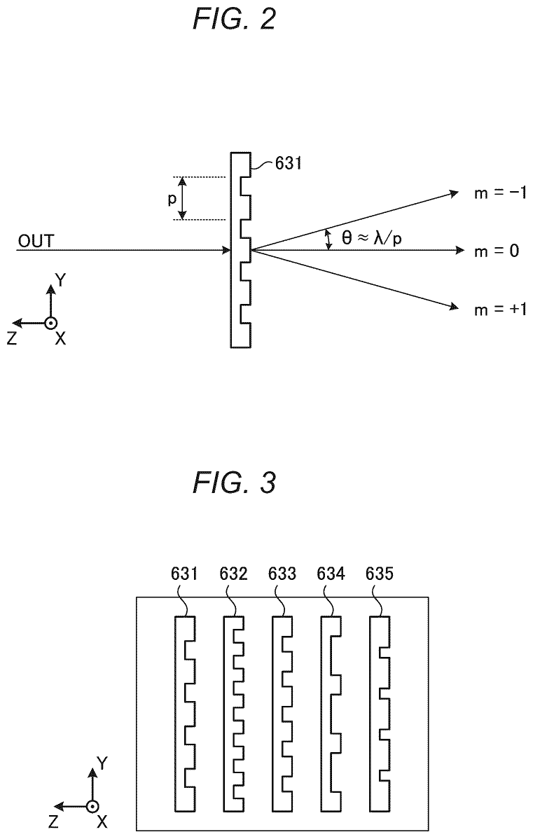

FIG. 2 is a cross-sectional view of a diffraction grating 631, which serves as a base of the diffractive optical element 63. The diffraction grating 631 is made of a material that transmits the pulse laser light Out having a wavelength k, and is a plate having a large number of grooves formed thereon and arranged at a grating period p. The pulse laser light Out having passed through the diffraction grating 631 is divided into multiple diffracted luminous fluxes including 0th-order diffracted luminous flux, −1st-order diffracted luminous flux, +1st-order diffracted luminous flux, and higher-order diffracted luminous fluxes that are not shown. In FIG. 2, m represents the order of the diffracted luminous fluxes. An angle θ between the direction in which the 0th-order diffracted luminous flux exits and the direction in which each of the −1st-order diffracted luminous flux and the +1st-order diffracted luminous flux exits is given approximately by λ/p when θ is very small. The energy of each of the diffracted luminous fluxes can also be determined by calculation. In general, a higher-order diffracted luminous flux higher than the −1st-order diffracted luminous flux and the +1st-order diffracted luminous flux has lower energy than the −1st order diffracted luminous flux and the +1st order diffracted luminous flux.

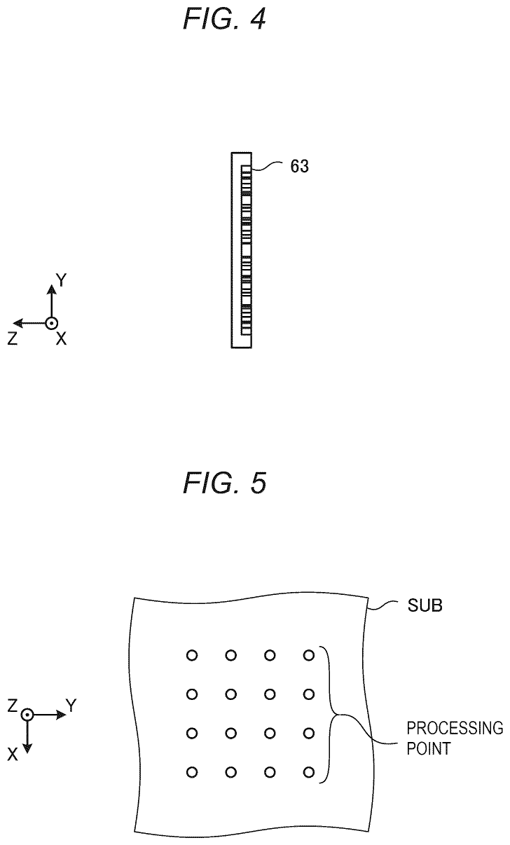

FIG. 3 shows a combination of multiple diffraction gratings 631 to 635 to illustrate the principle of the diffractive optical element 63. The diffractive optical element 63 can be so designed that multiple diffracted luminous fluxes are arranged in a desired pattern by appropriately combining the diffraction gratings 631 to 635 having different grating periods with one another. FIG. 4 shows an example of the thus designed diffractive optical element 63.

FIG. 5 shows an example of a pattern of the diffracted luminous fluxes radiated from the diffractive optical element 63 onto the workpiece SUB. For example, the diffractive optical element 63 is designed to output 16 diffracted luminous fluxes that each exit in a desired direction. The diffracted luminous fluxes are each focused by the focusing optical system 67 at a desired processing point on the workpiece SUB. As a result, 16 fine holes are simultaneously processed in the workpiece SUB. The 16 holes having a necessary depth are formed in one processing region by radiating the pulse laser light having radiated pulses the number of which is Nm with the position of the XYZ stage 501 fixed. The number of radiated pulses Nm is determined by dividing the necessary depth of the holes by the depth of the holes formed by one pulse of the pulse laser light Out. The step of radiating the pulse laser light having the number of radiated pulses Nm may be referred to as single laser processing. The point where the diffracted luminous fluxes are each focused to form a hole may be referred to as a processing point. After the single laser processing, the position of the XYZ stage 501 is controlled to form the sixteen holes in another processing region of the workpiece SUB.

It is conceivable to perform processing according to the pattern of a mask that is not shown by irradiating the workpiece SUB with the pulse laser light having passed through the mask and a transfer optical system, but a large amount of energy is lost at the mask. In contrast, patterned diffracted luminous fluxes formed by the diffractive optical element 63 can reduce the loss of energy, and improve the processing speed.

### 1.4 Processes Carried Out by Laser Processing Processor 53

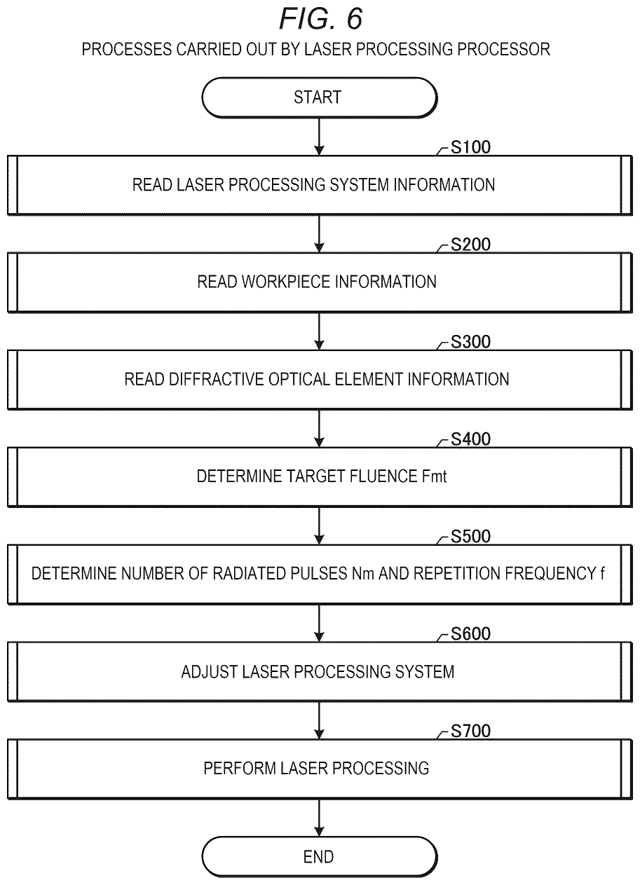

FIG. 6 is a flowchart showing laser processing processes in Comparative Example. In S100, the laser processing processor 53 reads information on the laser processing system. In S200, the laser processing processor 53 reads information on the workpiece SUB. In S300, the laser processing processor 53 reads information on the diffractive optical element 63. The information read in S100 to S300 may be read from the data managing server 93 or may be read from the memory 53a in the laser processing processor 53.

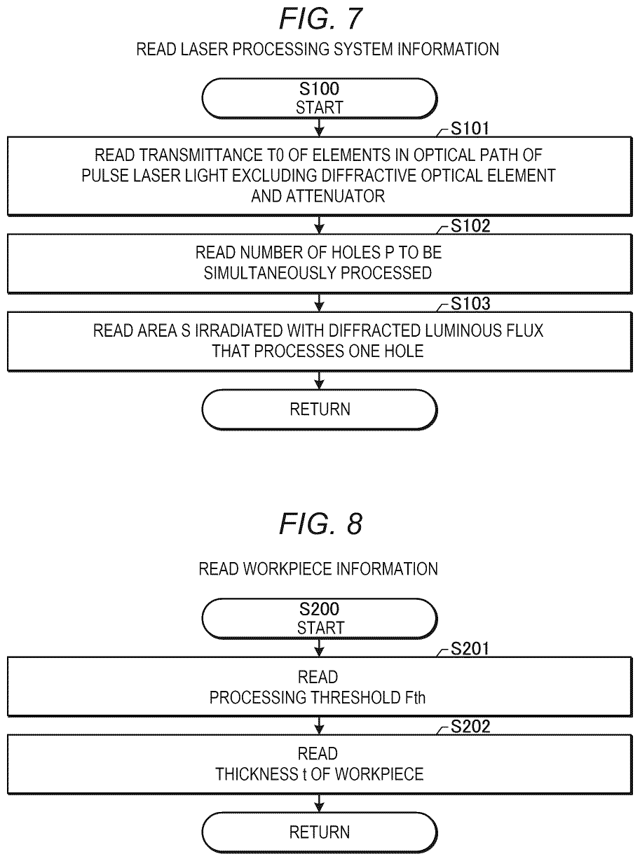

In S400, the laser processing processor 53 determines a target fluence Fmt at a processing point. In S500, the laser processing processor 53 determines the number of radiated pulses Nm and a repetition frequency f in the single laser processing. In S600, the laser processing processor 53 adjusts the laser processing system based on the target fluence Fmt. In S700, the laser processing processor 53 controls the laser processing system to cause it to perform the laser processing. The processes will be described below in detail with reference to FIGS. 7 to 14.

### 1.4.1 Read Laser Processing System Information

FIG. 7 is a flowchart showing the process of reading the information on the laser processing system in detail. The processes shown in FIG. 7 correspond to the subroutine labeled with S100 in FIG. 6.

In S101, the laser processing processor 53 reads transmittance TO of elements disposed in the optical path of the pulse laser light Out excluding the diffractive optical element 63 and the attenuator 52. The transmittance TO corresponds to the ratio of the energy of the light incident on the workpiece SUB to the energy of the pulse laser light Out output via the output coupling mirror 15 on the assumption that transmittance T_{DOE} of the diffractive optical element 63 and the transmittance Ta of the attenuator 52 are each 100%.

In S102, the laser processing processor 53 reads the number of holes P to be simultaneously processed. The number of holes P corresponds to the number of processing points, and is 16 in the example shown in FIG. 5.

In S103, the laser processing processor 53 reads an irradiated area S of the surface of the workpiece SUB, which is irradiated with one of the diffracted luminous fluxes that processes one hole. When the beam of one of the diffracted luminous fluxes at the surface of the workpiece SUB has a circular cross-sectional shape having a diameter D, the irradiated area S is given by π(D/2)².

After S103, the laser processing processor 53 terminates the processes in the present flowchart, and returns to the processes shown in FIG. 6.

### 1.4.2 Read Workpiece Information

FIG. 8 is a flowchart showing the process of reading the information on the workpiece SUB in detail. The processes shown in FIG. 8 correspond to the subroutine labeled with S200 in FIG. 6.

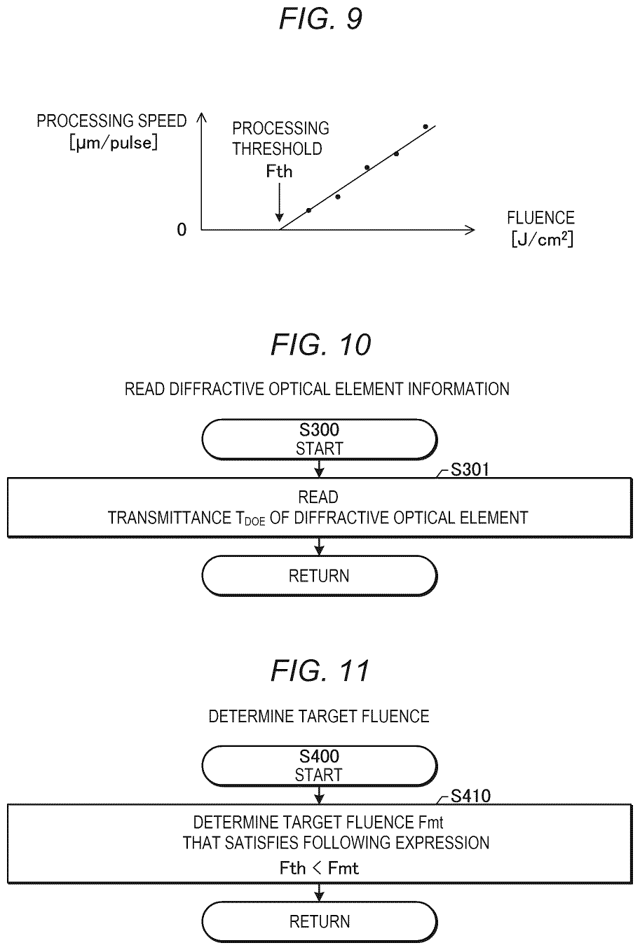

In S201, the laser processing processor 53 reads a processing threshold Fth for the workpiece SUB. The processing threshold Fth is a threshold of the fluence of diffracted luminous flux used to process the workpiece SUB. When the workpiece SUB is irradiated with the pulse laser light having a fluence smaller than or equal to the processing threshold Fth, the workpiece SUB is not processed, whereas when the workpiece SUB is irradiated with the pulse laser light having a fluence greater than the processing threshold Fth, the workpiece SUB is processed. The processing threshold Fth will be described later with reference to FIG. 9.

In S202, the laser processing processor 53 reads a thickness t of the workpiece SUB. To form a through hole in the workpiece SUB, the value as a result of multiplication of the depth of the hole to be formed by one pulse of the pulse laser light and the number of radiated pulses Nm only needs to be greater than or equal to the thickness t.

After S202, the laser processing processor 53 terminates the processes in the present flowchart, and returns to the processes shown in FIG. 6.

FIG. 9 is a graph showing an example of the definition of the processing threshold Fth. In FIG. 9, the horizontal axis represents the fluence of a diffracted luminous flux, and the vertical axis represents the processing speed. The processing speed corresponds to the depth of the hole per radiated pulse of the pulse laser light. In a graph representing the fluence and the processing speed based on a result of measurement, the horizontal-axis value of the intersection of a straight line that approximates the graph and the horizontal axis, where the processing speed is zero, is the processing threshold Fth.

### 1.4.3 Read Diffractive Optical Element Information

FIG. 10 is a flowchart showing the process of reading the information on the diffractive optical element 63 in detail. The process shown in FIG. 10 corresponds to the subroutine labeled with S300 in FIG. 6.

In S301, the laser processing processor 53 reads the transmittance T_{DOE} of the diffractive optical element 63.

The information on the diffractive optical element 63 may include the number of diffracted luminous fluxes Ln. The process of reading the information on the diffractive optical element 63 may include the steps of reading the number of the diffracted luminous fluxes Ln and ascertaining that the number of the diffracted luminous fluxes Ln coincides with the number of holes P to be simultaneously processed (see FIG. 7).

After S301, the laser processing processor 53 terminates the process in the present flowchart, and returns to the processes shown in FIG. 6.

### 1.4.4 Determine Target Fluence

FIG. 11 is a flowchart showing the process of determining the target fluence Fmt at a processing point in detail. The process shown in FIG. 11 corresponds to the subroutine labeled with S400 in FIG. 6.

In S410, the laser processing processor 53 determines the target fluence Fmt that satisfies the following expression:

Fth<Fmt

When the workpiece SUB is irradiated with the pulse laser light having a fluence greater than the processing threshold Fth, the workpiece SUB is processed.

After S410, the laser processing processor 53 terminates the process in the present flowchart, and returns to the processes shown in FIG. 6.

### 1.4.5 Determine Number of Radiated Pulses Nm and Repetition Frequency f

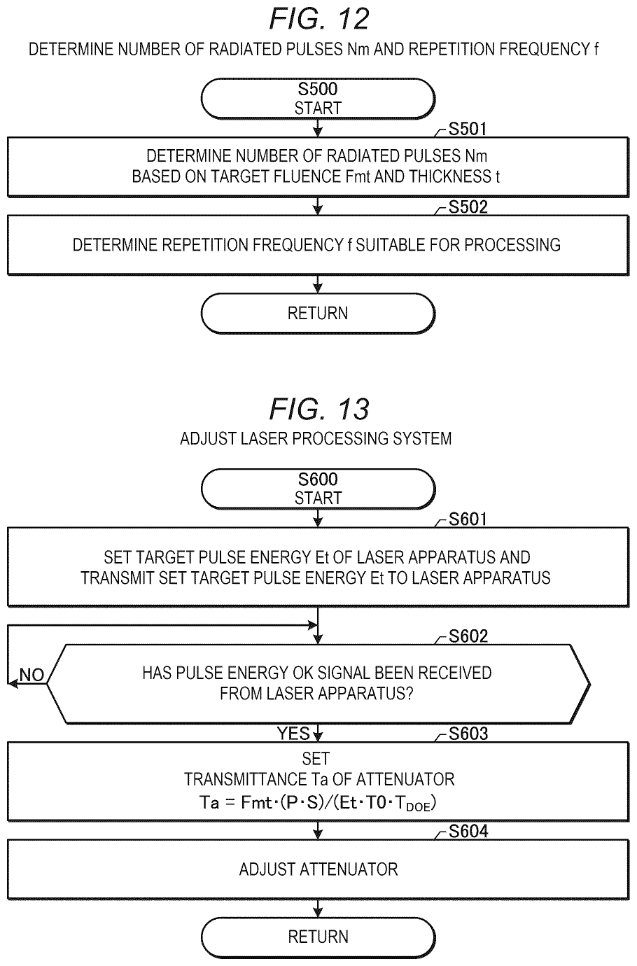

FIG. 12 is a flowchart showing details of the process of determining the number of radiated pulses Nm and the repetition frequency f in the single laser processing. The processes shown in FIG. 12 correspond to the subroutine labeled with S500 in FIG. 6.

In S501, the laser processing processor 53 determines the number of radiated pulses Nm based on the target fluence Fmt and thickness t.

In S502, the laser processing processor 53 determines the repetition frequency f suitable for the processing. The repetition frequency f is set at a value within the range of the rated repetition frequency of the laser apparatus 1. However, when the repetition frequency f is too high, the shape of the holes formed in the workpiece SUB may vary, and it is desirable to set the repetition frequency f at a value within a range over which the variation is suppressed.

After S502, the laser processing processor 53 terminates the processes in the present flowchart, and returns to the processes shown in FIG. 6.

### 1.4.6 Adjust Laser Processing System

FIG. 13 is a flowchart showing details of the process for adjusting the laser processing system based on the target fluence Fmt. The processes shown in FIG. 13 correspond to the subroutine labeled with S600 in FIG. 6.

In S601, the laser processing processor 53 sets the target pulse energy Et of the laser apparatus 1 and transmits the set target pulse energy Et to the laser apparatus 1. The target pulse energy Et is pulse energy that falls within a range over which the performance of the laser apparatus 1 can be maintained.

The laser control processor 13 of the laser apparatus 1 having received the target pulse energy Et closes the shutter 19, and controls the laser apparatus 1 to cause it to perform adjustment oscillation based on the target pulse energy Et. The laser control processor 13 outputs a pulse energy OK signal when the value of the pulse energy of the pulse laser light Out measured by the monitor module 16 becomes stable within an allowable range including the target pulse energy Et and values therearound.

In S602, the laser processing processor 53 determines whether the pulse energy OK signal has been received from the laser apparatus 1. When the pulse energy OK signal has not been received (NO in S602), the laser processing processor 53 waits until the pulse energy OK signal is received. When the pulse energy OK signal has been received (YES in S602), the laser processing processor 53 proceeds to the process in S603.

In S603, the laser processing processor 53 sets the transmittance Ta of the attenuator 52 as shown below.

The pulse energy of the light that passes through the focusing optical system 67 and is incident on the workpiece SUB is expressed by the following equality:

Et·Ta·T0·T_{DOE}=Fmt·P·S

From the expression, the transmittance Ta of the attenuator 52 is calculated as follows:

Ta=Fmt·P·S/(Et·T0·T_{DOE})

In S604, the laser processing processor 53 adjusts the attenuator 52 based on the transmittance Ta. As a result, the pulse energy of the pulse laser light Out to be incident on the diffractive optical element 63 can be adjusted, and the fluence at the processing point can be set at a value close to the target fluence Fmt.

However, an adjustment mechanism that adjusts the pulse energy of the pulse laser light Out to be incident on the diffractive optical element 63 is not limited to the attenuator 52. The pulse energy of the pulse laser light Out incident on the diffractive optical element 63 may be controlled by adjusting the target pulse energy Et of the pulse laser light Out output via the output coupling mirror 15, and the adjustment mechanism in this case is the power supply apparatus 12.

After S604, the laser processing processor 53 terminates the processes in the present flowchart, and returns to the processes shown in FIG. 6.

### 1.4.7 Laser Processing

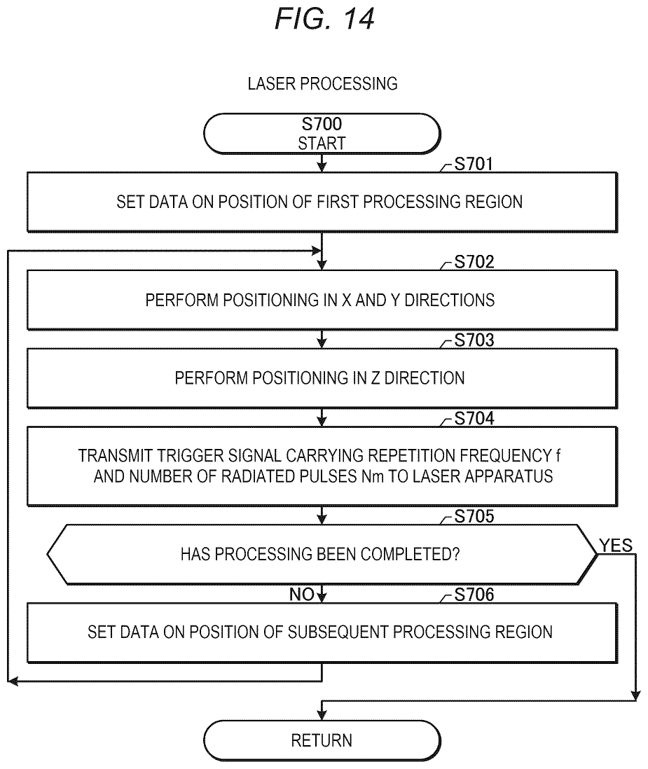

FIG. 14 is a flowchart showing the process of performing the laser processing in detail. The processes shown in FIG. 14 correspond to the subroutine labeled with S700 in FIG. 6.

In S701, the laser processing processor 53 sets data on the position of the XYZ stage 501 in such a way that a first processing region of the workpiece SUB is irradiated with the diffracted luminous fluxes.

In S702, the laser processing processor 53 positions the XYZ stage 501 in the X and Y directions in accordance with the set position data.

In S703, the laser processing processor 53 positions the XYZ stage 501 in the Z direction in accordance with the set position data.

In S704, the laser processing processor 53 transmits a trigger signal carrying the repetition frequency f and the number of radiated pulse Nm to the laser apparatus 1. The single laser processing is thus performed.

In S705, the laser processing processor 53 determines whether the processing of the workpiece SUB has been completed. When there are regions that have not been processed (NO in S705), the laser processing processor 53 proceeds to the process in S706. When all the processing regions have been processed (YES in S705), the laser processing processor 53 terminates the processes in the present flowchart, and returns to the processes shown in FIG. 6.

In S706, the laser processing processor 53 sets the data on the position of the XYZ stage 501 in such a way that the subsequent processing region is irradiated with the diffracted luminous fluxes. After S706, the laser processing processor 53 returns the process in S702.

1.5 Problems with Comparative Example

FIG. 15 shows another example of the pattern of the diffracted luminous fluxes radiated from the diffractive optical element 63 onto the workpiece SUB. The diffracted luminous fluxes output from the diffractive optical element 63 are not limited only to the diffracted luminous fluxes necessary for the laser processing. That is, the multiple diffracted luminous fluxes, into which the pulse laser light Out is divided by the diffractive optical elements 63 and with which the workpiece SUB is irradiated, may include not only the diffracted luminous fluxes that are focused at desired processing points on the workpiece SUB but also diffracted luminous fluxes that are focused at non-processing points that are not intended to be processed. The diffracted luminous fluxes focused at the processing points on the workpiece SUB are hereinafter referred to as first diffracted luminous fluxes, and the diffracted luminous fluxes focused at the non-processing points on the workpiece SUB are hereinafter referred to as second diffracted luminous fluxes. The first diffracted luminous fluxes are diffracted luminous fluxes necessary for the laser processing, and the second diffracted luminous fluxes are diffracted luminous fluxes unnecessary for the laser processing. It is noted that not every diffracted luminous flux unnecessary for the laser processing is irradiated onto the workpiece SUB. For example, higher-order diffracted luminous fluxes out of the luminous fluxes diffracted by the diffractive optical element 63 may exit outward from the focusing optical system 67, or may be incident on a circumferential wall of an aperture that is not shown but is separately provided, and may therefore not be radiated onto the workpiece SUB.

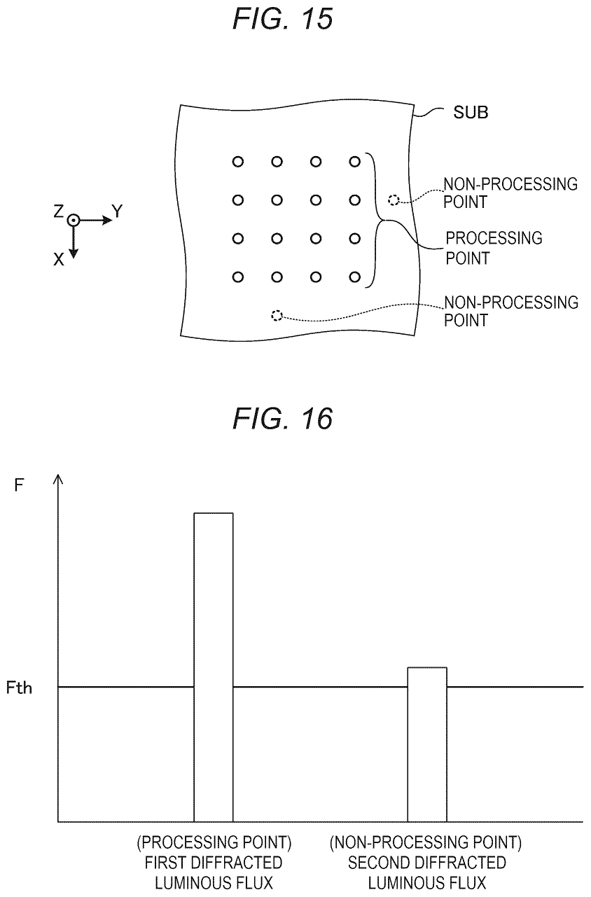

FIG. 16 is a bar graph showing a problem with Comparative Example. In FIG. 16, the horizontal axis shows the first and second diffracted luminous fluxes, and the vertical axis represents the fluence F of each of the diffracted luminous fluxes at the surface of the workpiece SUB. When the pulse energy of the pulse laser light Out incident on the diffractive optical element 63 is increased, the fluence of the first diffracted luminous fluxes increases, and it is therefore believed that the efficiency of the laser processing can be improved. However, when the pulse energy of the pulse laser light Out is increased, the fluence of the second diffracted luminous fluxes also increases in conjunction with the first diffracted luminous fluxes. When the fluence of the second diffracted luminous fluxes exceeds the processing threshold Fth, holes may also be formed at the non-processing points on the workpiece SUB.

2. Laser Processing System in which Target Fluence is so Set that Fluence of Second Diffracted Luminous Fluxes is Smaller than or Equal to Processing Threshold Fth

### 2.1 Concept

### 2.1.1 Fluences of First and Second Diffracted Luminous Fluxes

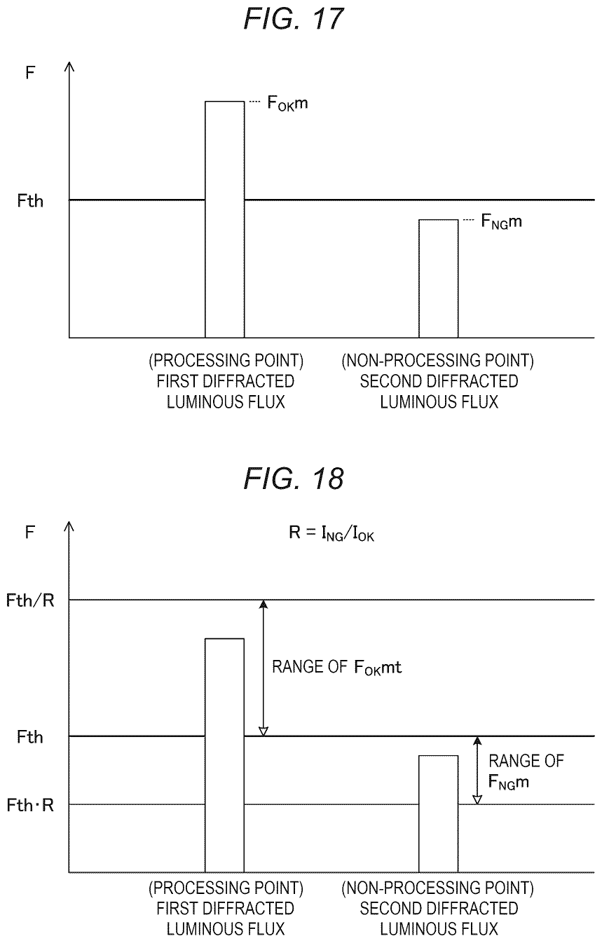

FIG. 17 is a bar graph showing an example of the result of control in a first embodiment. In FIG. 17, the horizontal axis shows the first and second diffracted luminous fluxes, and the vertical axis represents the fluence F of each of the diffracted luminous fluxes at the surface of the workpiece SUB. In the first embodiment, the laser processing processor 53 controls the adjustment mechanism, such as the attenuator 52, in such a way that a fluence F_{OK}m of the first diffracted luminous fluxes is greater than the processing threshold Fth and a fluence F_{NG}m of the second diffracted luminous fluxes is smaller than or equal to the processing threshold Fth.

### 2.1.2 Set Target Fluence F_{OK}mt

In the first embodiment, a target fluence F_{OK}mt of the first diffracted luminous fluxes is set as shown below. When the fluence F_{OK}m of the first diffracted luminous fluxes is controlled to the target fluence F_{OK}mt, the fluence F_{NG}m of the second diffracted luminous fluxes is determined in accordance with an optical intensity ratio R of the optical intensity of the second diffracted luminous fluxes to that of the first diffracted luminous fluxes.

FIG. 18 is a bar graph showing an example of the target fluence F_{OK}mt of the first diffracted luminous fluxes that is set in the first embodiment. In FIG. 18, the horizontal axis shows the first and second diffracted luminous fluxes, and the vertical axis represents the fluence F of each of the diffracted luminous fluxes at the surface of the workpiece SUB. In FIG. 18 and FIGS. 25, 34, 40, 41, and 48, the latter five of which will be described later, vertical arrows indicate the range of a value, black arrows each indicate that the value indicated by the tip of the arrow falls within the range, and white arrows each indicate that the value indicated by the tip of the arrow does not fall within the range.

### 2.1.2.1 Lower Limit of Target Fluence F_{OK}mt

The target fluence F_{OK}mt is set at a value greater than the processing threshold Fth. As a result, the fluence F_{OK}m of the first diffracted luminous fluxes is greater than the processing threshold Fth.

### 2.1.2.2 Upper Limit of Target Fluence F_{OK}mt

It is assumed that the optical intensity ratio R is a value as a result of division of an optical intensity I_{NG} of the second diffracted luminous fluxes at the surface of the workpiece SUB by an optical intensity I_{OK} of the first diffracted luminous fluxes at the surface of the workpiece SUB, as expressed by the following expression:

R=I_{NG}/I_{OK}

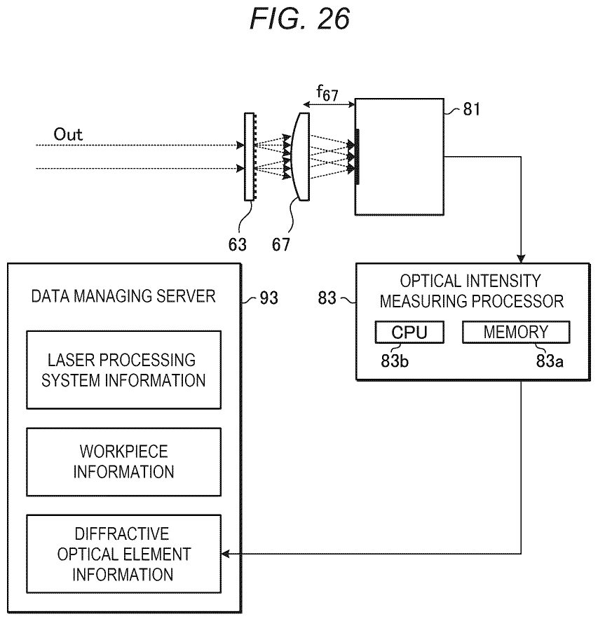

The optical intensity I_{OK} of the first diffracted luminous fluxes and the optical intensity I_{NG} of the second diffracted luminous fluxes are measured, for example, by using a measurement system that will be described with reference to FIG. 26. The optical intensities may instead be determined by a simulation of diffracted luminous fluxes based on design data on the diffractive optical element 63. When the optical intensity I_{OK} of the first diffracted luminous fluxes varies, the average of the varying optical intensity I_{OK} is used to calculate the optical intensity ratio R. When the optical intensity I_{NG} of the second diffracted luminous fluxes varies, the average of the varying optical intensity I_{NG} is used to calculate the optical intensity ratio R.

The target fluence F_{OK}mt is set at a value smaller than or equal to a value Fth/R, which is a result of division of the processing threshold Fth by the optical intensity ratio R. Setting the target fluence F_{OK}mt at a value smaller than or equal to the value Fth/R causes the fluence F_{NG}m of the second diffracted luminous fluxes to be a value smaller than or equal to the processing threshold Fth. Setting the target fluence F_{OK}mt at a value greater than the processing threshold Fth causes the fluence F_{NG}m of the second diffracted luminous fluxes to be a value greater than the value Fth·R.

### 2.1.2.3 Range of Target Fluence F_{OK}mt

FIG. 18 and the description thereof show that setting the target fluence F_{OK}mt at a value that falls within the range shown below causes the fluence F_{OK}m of the first diffracted luminous fluxes to be a value greater than the processing threshold Fth, and the fluence F_{NG}m of the second diffracted luminous fluxes to be a value smaller than or equal to the processing threshold Fth.

Fth<F_{OK}mt≤Fth/R

### 2.2 Configuration of Laser Processing System

The configuration of the laser processing system according to the first embodiment is the same as the configuration in Comparative Example described with reference to FIG. 1.

### 2.3 Processes Carried Out by Laser Processing Processor 53

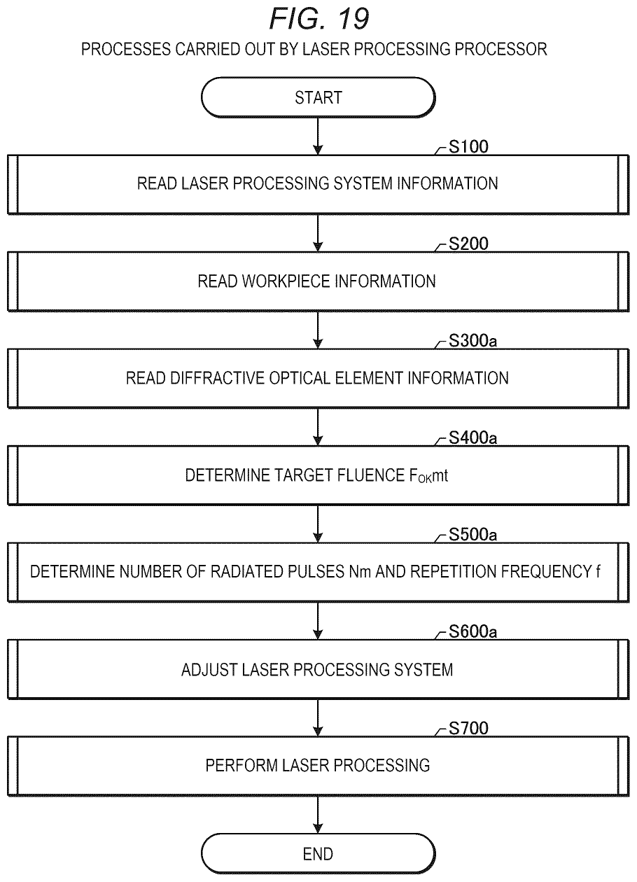

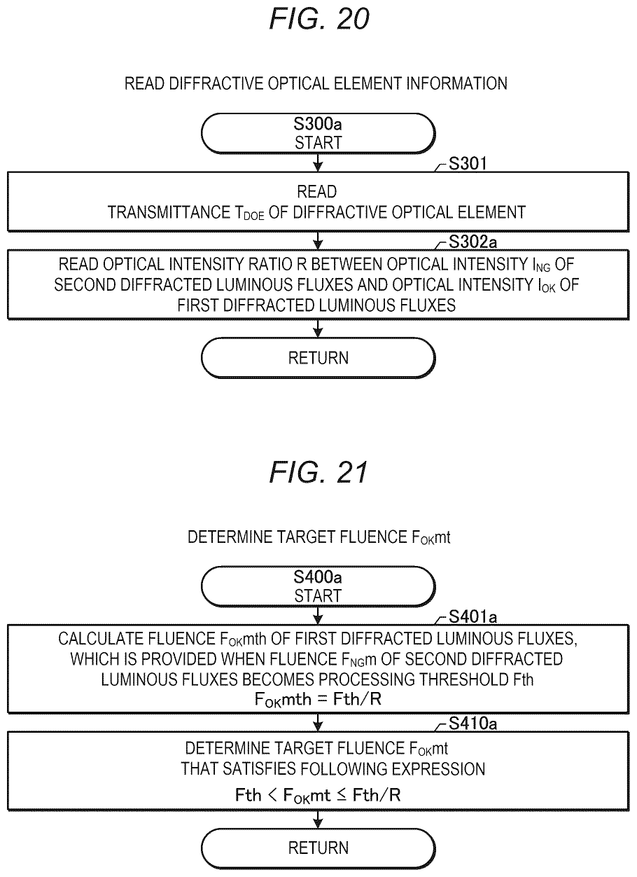

FIG. 19 is a flowchart showing laser processing processes in the first embodiment. Out of the laser processing processes in the first embodiment, the processes in S300a, S400a, S500a and S600a differ from the corresponding processes in Comparative Example. The different processes will be described below in detail with reference to FIGS. 20 to 23.

### 2.3.1 Read Diffractive Optical Element Information

FIG. 20 is a flowchart showing the process of reading information on the diffractive optical element 63 in detail. The processes shown in FIG. 20 correspond to the subroutine labeled with S300a in FIG. 19.

In S301, the laser processing processor 53 reads the transmittance T_{DOE} of the diffractive optical element 63. This point is the same as that in Comparative Example.

In S302a, the laser processing processor 53 reads the value of the optical intensity ratio R. The optical intensity ratio R is used in S401a, which will be described with reference to FIG. 21.

After S302a, the laser processing processor 53 terminates the processes in the present flowchart, and returns to the processes shown in FIG. 19.

### 2.3.2 Determine Target Fluence

FIG. 21 is a flowchart showing the process of determining the target fluence F_{OK}mt at a processing point in detail. The processes shown in FIG. 21 correspond to the subroutine labeled with S400a in FIG. 19.

In S401a, the laser processing processor 53 calculates a fluence F_{OK}mth of the first diffracted luminous fluxes, which is provided when the fluence F_{NG}m of the second diffracted luminous fluxes becomes the processing threshold Fth, using the following expression:

F_{OK}mth=Fth/R

In S410a, the laser processing processor 53 determines the target fluence F_{OK}mt that satisfies the following expression:

Fth<F_{OK}mt≤Fth/R

The target fluence F_{OK}mt may be set at Fth/R, which is the upper limit. This can maximize the efficiency of the laser processing while suppressing the processing performed at the non-processing points that require no processing. The target fluence F_{OK}mt may instead be set at the average of Fth and Fth/R. In this case, even when the pulse energy of the pulse laser light Out unexpectedly varies, a situation in which the processing is performed at the non-processing points or a situation in which sufficient processing is not performed at the processing points that require the processing can be avoided.

After S410a, the laser processing processor 53 terminates the processes in the present flowchart, and returns to the processes shown in FIG. 19.

### 2.3.3 Determine Number of Radiated Pulses Nm and Repetition Frequency f

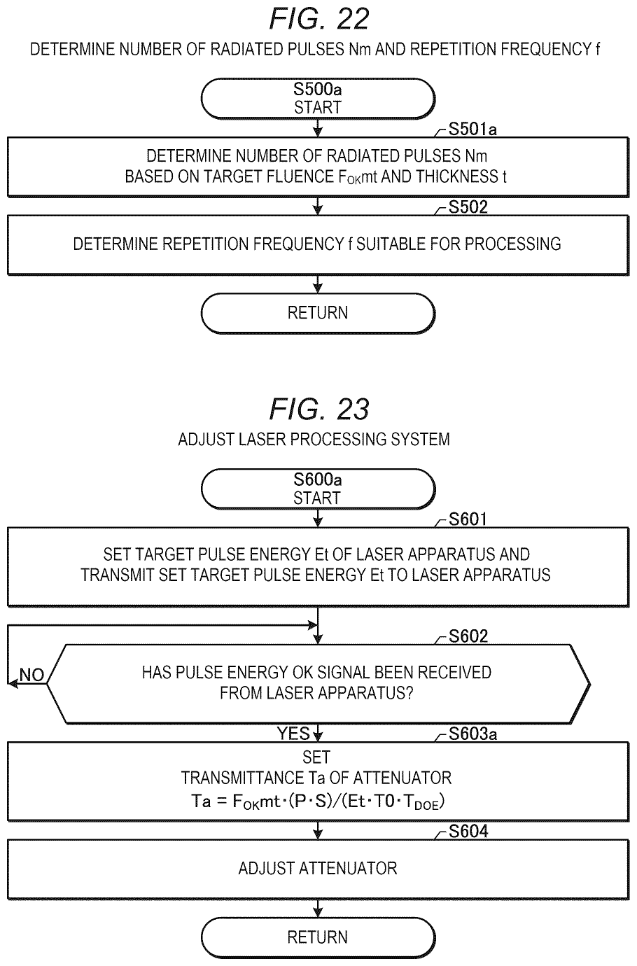

FIG. 22 is a flowchart showing details of the process of determining the number of radiated pulses Nm and the repetition frequency f in the single laser processing. The processes shown in FIG. 22 correspond to the subroutine labeled with S500a in FIG. 19.

In S501a, the laser processing processor 53 determines the number of radiated pulses Nm based on the target fluence F_{OK}mt and the thickness t.

In S502, the laser processing processor 53 determines the repetition frequency f suitable for the processing. This point is the same as that in Comparative Example.

After S502, the laser processing processor 53 terminates the processes in the present flowchart, and returns to the processes shown in FIG. 19.

### 2.3.4 Adjust Laser Processing System

FIG. 23 is a flowchart showing details of the process of adjusting the laser processing system based on the target fluence F_{OK}mt. The processes shown in FIG. 23 correspond to the subroutine labeled with S600a in FIG. 19.

The processes shown in FIG. 23 differ from those in Comparative Example shown in FIG. 13 in terms of expression for setting the transmittance Ta of the attenuator 52 in S603a. The transmittance Ta of the attenuator 52 is calculated by the following expression, and the target fluence F_{OK}mt is used in place of the target fluence Fmt.

Ta=F_{OK}mt·P·S/(Et·T0·T_{DOE})

In the first embodiment, to calculate the transmittance Ta of the attenuator 52, it is assumed that the sum of the pulse energy values of the second diffracted luminous fluxes out of the pulse laser light Out incident on the diffractive optical element 63 be sufficiently smaller than the pulse energy of the pulse laser light Out.

The processes shown in FIG. 23 are otherwise the same as the processes shown in FIG. 13.

### 2.4 Effects

(1) According to the first embodiment, the laser processing system includes the laser apparatus 1, the diffractive optical element 63, the focusing optical system 67, the adjustment mechanism, such as the attenuator 52, and the laser processing processor 53. The laser apparatus 1 outputs the pulse laser light Out. The diffractive optical element 63 divides the pulse laser light Out into luminous fluxes containing the first diffracted luminous fluxes, which are multiple diffracted luminous fluxes radiated to multiple processing points on the workpiece SUB, and the second diffracted luminous fluxes, which are multiple diffracted luminous fluxes radiated to multiple non-processing points. The focusing optical system 67 focuses each of the first and second diffracted luminous fluxes at the workpiece SUB. The adjustment mechanism is configured to be capable of adjusting the pulse energy of the pulse laser light Out to be incident on the diffractive optical element 63. The laser processing processor 53 controls the adjustment mechanism in such a way that the conditions described below are satisfied based on parameters including the processing threshold Fth of the fluence for processing the workpiece SUB. (a) The fluence F_{OK}m of the first diffracted luminous fluxes at the surface of the workpiece SUB is greater than the processing threshold Fth. (b) The fluence F_{NG}m of the second diffracted luminous fluxes at the surface of the workpiece SUB is smaller than or equal to the processing threshold Fth.

When the conditions described above are satisfied, the fluence F_{OK}m of the first diffracted luminous fluxes radiated to the processing points is greater than the processing threshold Fth, and the fluence F_{NG}m of the second diffracted luminous fluxes radiated to the non-processing points is smaller than or equal to the processing threshold Fth, so that required processing can be performed with unnecessary processing suppressed.

(2) According to the first embodiment, the laser processing processor 53 controls the adjustment mechanism such as the attenuator 52 by setting the target fluence F_{OK}mt, which is the target value of the fluence F_{OK}m of the first diffracted luminous fluxes, as follows: (a) The target fluence F_{OK}mt is greater than the processing threshold Fth. (b) The target fluence F_{OK}mt is smaller than or equal to the value Fth/R, which is a result of division of the processing threshold Fth by the optical intensity ratio R, which is a result of division of the optical intensity I_{NG} of the second diffracted luminous fluxes at the surface of the workpiece SUB by the optical intensity I_{OK} of the first diffracted luminous fluxes at the surface of the workpiece SUB.

With the conditions described above satisfied, when the target fluence F_{OK}mt of the first diffracted luminous fluxes is set, the optical intensity ratio R can be used to cause not only the fluence F_{OK}m of the first diffracted luminous fluxes but also the fluence F_{NG}m of the second diffracted luminous fluxes to each fall within a desired range.

The first embodiment is otherwise the same as Comparative Example.

### 3. Laser Processing System in Consideration of Variation in Fluence Between First Diffracted Luminous Fluxes and Between Second Diffracted Luminous Fluxes

### 3.1 Concept

### 3.1.1 Fluences of First and Second Diffracted Luminous Fluxes

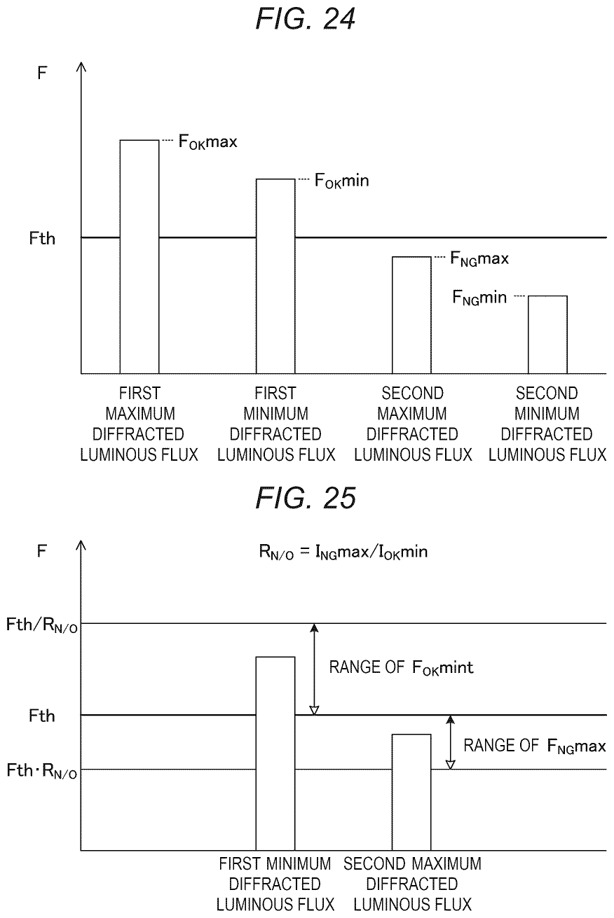

FIG. 24 is a bar graph showing an example of the result of control in a second embodiment. In the second embodiment, variation in fluence between the first diffracted luminous fluxes focused at the processing points and variation in fluence between the second diffracted luminous fluxes focused at the non-processing points are taken into consideration. The diffracted luminous flux having the maximum fluence out of the first diffracted luminous fluxes is called a first maximum diffracted luminous flux, and the fluence of the first maximum diffracted luminous flux is called F_{OK}max. The diffracted luminous flux having the minimum fluence out of the first diffracted luminous fluxes is called a first minimum diffracted luminous flux, and the fluence of the first minimum diffracted luminous flux is called F_{OK}min. The diffracted luminous flux having the maximum fluence out of the second diffracted luminous fluxes is called a second maximum diffracted luminous flux, and the fluence of the second maximum diffracted luminous flux is called F_{NG}max. The diffracted luminous flux having the minimum fluence out of the second diffracted luminous fluxes is called a second minimum diffracted luminous flux, and the fluence of the second minimum diffracted luminous flux is called F_{NG}min.

In FIG. 24, the horizontal axis shows the first maximum diffracted luminous flux, the first minimum diffracted luminous flux, the second maximum diffracted luminous flux, and the second minimum diffracted luminous flux, and the vertical axis represents the fluence F of each of the diffracted luminous fluxes at the surface of the workpiece SUB. In the second embodiment, the laser processing processor 53 controls the adjustment mechanism such as the attenuator 52 in such a way that the fluence F_{OK}min of the first minimum diffracted luminous flux is greater than the processing threshold Fth and the fluence F_{NG}max of the second maximum diffracted luminous flux is smaller than or equal to the processing threshold Fth.

### 3.1.2 Set Target Fluence F_{OK}mint

In the second embodiment, a target fluence F_{OK}mint of the first minimum diffracted luminous flux is set as shown below. When the fluence F_{OK}min of the first minimum diffracted luminous flux is controlled to be the target fluence F_{OK}mint, the fluence of each of the first maximum diffracted luminous flux, the second maximum diffracted luminous flux, and the second minimum diffracted luminous flux is a value determined in accordance with the optical intensity ratio of the diffracted luminous flux to the first minimum diffracted luminous flux.

FIG. 25 is a bar graph showing an example of the target fluence F_{OK}mint of the first minimum diffracted luminous flux that is set in the second embodiment. In FIG. 25, the horizontal axis shows the first minimum diffracted luminous flux and the second maximum diffracted luminous flux, and the vertical axis represents the fluence F of each of the diffracted luminous fluxes at the surface of the workpiece SUB.

### 3.1.2.1 Lower Limit of Target Fluence F_{OK}mint

The target fluence F_{OK}mint is set at a value greater than the processing threshold Fth. As a result, the fluence F_{OK}min of the first minimum diffracted luminous flux is greater than the processing threshold Fth. The fluences of the first diffracted luminous fluxes including the fluence F_{OK}max of the first maximum diffracted luminous flux, which are all greater than or equal to the fluence F_{OK}min of the first minimum diffracted luminous flux, are also greater than the processing threshold Fth.

### 3.1.2.2 Upper Limit of Target Fluence F_{OK}mint

An optical intensity ratio R_{N/O} is assumed to be a value as a result of division of an optical intensity I_{NG}max of the second maximum diffracted luminous flux at the surface of the workpiece SUB by an optical intensity I_{OK}min of the first minimum diffracted luminous flux at the surface of the workpiece SUB, as expressed by the following expression:

R_{N/O}=I_{NG}max/I_{OK}min

The target fluence F_{OK}mint is set at a value smaller than or equal to a value Fth/R_{N/O} as a result of division of the processing threshold Fth by the optical intensity ratio R_{N/O}. Setting the target fluence F_{OK}mint at a value smaller than or equal to the value Fth/R_{N/O} causes the fluence F_{NG}max of the second maximum diffracted luminous flux to be a value smaller than or equal to the processing threshold Fth. The fluences of the second diffracted luminous fluxes including the fluence F_{NG}min of the second minimum diffracted luminous flux, which are all smaller than or equal to the fluence F_{NG}max of the second maximum diffracted luminous flux, are also smaller than or equal to the processing threshold Fth. It is noted that setting the target fluence F_{OK}mint at a value greater than the processing threshold Fth causes the fluence F_{NG}max of the second maximum diffracted luminous flux to be a value greater than a value Fth·R_{N/O}.

### 3.1.2.3 Range of Target Fluence F_{OK}mint

FIG. 25 and the description thereof show that setting the target fluence F_{OK}mint at a value that falls within the range shown below causes the fluence F_{OK}min of the first minimum diffracted luminous flux to be a value greater than the processing threshold Fth, and the fluence F_{NG}max of the second maximum diffracted luminous flux to be a value smaller than or equal to the processing threshold Fth.

Fth<F_{OK}mint≤Fth/R_{N/O}

### 3.2 Configuration of Laser Processing System

The configuration of the laser processing system according to the second embodiment is the same as the configuration in Comparative Example described with reference to FIG. 1.

### 3.3 Measurement of Diffractive Optical Element Information

FIG. 26 schematically shows the configuration of a measurement system that measures information on the diffractive optical element 63 in the second embodiment. In the optical system including the diffractive optical element 63 and the focusing optical system 67 shown in FIG. 1, an image sensor 81 is disposed at a position separate from the focusing optical system 67 by the focal length f₆₇ in place of the workpiece SUB. The measurement system may be provided separately from the laser processing apparatus 5, or may be provided inside the laser processing apparatus 5.

The image sensor 81 is connected to an optical intensity measuring processor 83, and the optical intensity measuring processor 83 is connected to the data managing server 93. The optical intensity measuring processor 83 is a processing apparatus including a memory 83a, which stores a control program, and a CPU 83b, which executes the control program. The optical intensity measuring processor 83 is specially configured or programmed to carry out various processes described in the present disclosure.

The pulse laser light Out incident on the diffractive optical element 63 has the same wavelength λ as the pulse laser light Out output from the laser apparatus 1. The image sensor 81 outputs image data containing the optical intensity at each position on the light receiving surface of the image sensor 81 or a time integral value of the optical intensity. The optical intensity measuring processor 83 measures the optical intensities of the first and second diffracted luminous fluxes based on the image data output from the image sensor 81.

The optical intensities of the first and second diffracted luminous fluxes are not limited to the actually measured values measured by using the measurement system shown in FIG. 26, and may instead be determined by a simulation of the diffracted luminous fluxes based on the design data on the diffractive optical element 63.

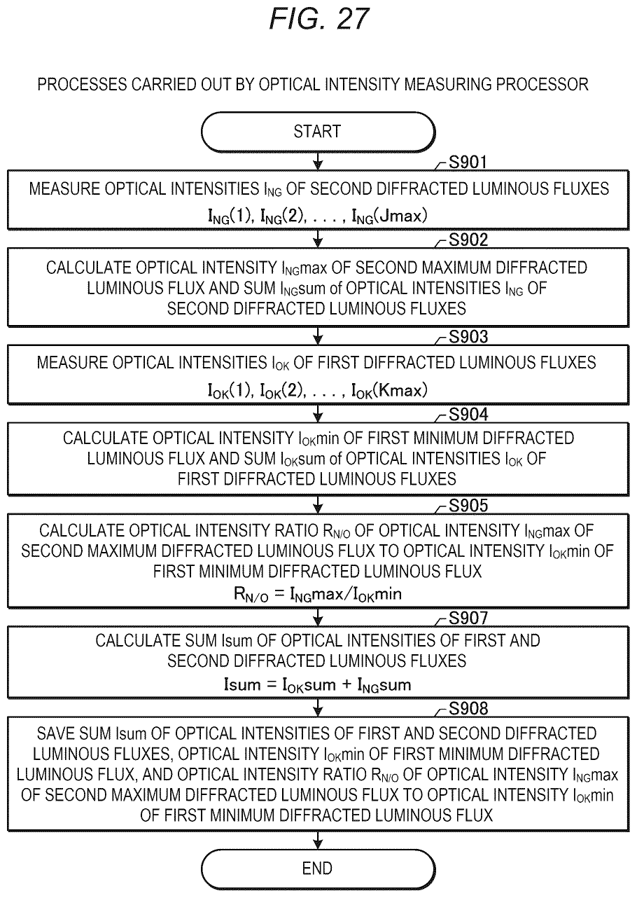

FIG. 27 is a flowchart showing the process of measuring optical intensities in the second embodiment. The processes shown below allow the optical intensity measuring processor 83 to measure the optical intensities of the diffracted luminous fluxes to acquire information on the diffractive optical element 63.

In S901, the optical intensity measuring processor 83 measures the optical intensities I_{NG} of the second diffracted luminous fluxes. Let Jmax be the number of the second diffracted luminous fluxes, and the optical intensities I_{NG} of the second diffracted luminous fluxes can be expressed in the form of the following data sequence:
I_{NG}(1), I_{NG}(2), . . . , I_{NG}(Jmax)

In S902, the optical intensity measuring processor 83 calculates the following values:
Optical intensity I_{NG}max of second maximum diffracted luminous flux
Sum I_{NG}sum of optical intensities I_{NG} of second diffracted luminous fluxes

The optical intensity I_{NG}max of the second maximum diffracted luminous flux is the maximum of the optical intensities I_{NG} of the second diffracted luminous fluxes. The sum I_{NG}sum of the optical intensities I_{NG} of the second diffracted luminous fluxes is a value calculated by I_{NG}(1)+I_{NG}(2)+ . . . +I_{NG}(Jmax).

In S903, the optical intensity measuring processor 83 measures the optical intensities I_{OK} of the first diffracted luminous fluxes. Let Kmax be the number of the first diffracted luminous fluxes, and the optical intensities I_{OK} of the first diffracted luminous fluxes can be expressed in the form of the following data sequence:
I_{OK}(1), I_{OK}(2), . . . , I_{OK}(Kmax)

In S904, the optical intensity measuring processor 83 calculates the following values:
Optical intensity I_{OK}min of first minimum diffracted luminous flux
Sum I_{OK}sum of optical intensities I_{OK} of first diffracted luminous fluxes

The optical intensity I_{OK}min of the first minimum diffracted luminous flux is the minimum of the optical intensities I_{OK} of the first diffracted luminous fluxes. The sum I_{OK}sum of the optical intensities I_{OK} of the first diffracted luminous fluxes is a value calculated by I_{OK}(1)+I_{OK}(2)+ . . . +I_{OK}(Kmax).

In S905, the optical intensity measuring processor 83 calculates the optical intensity ratio R_{N/O} of the optical intensity I_{NG}max of the second maximum diffracted luminous flux to the optical intensity I_{OK}min of the first minimum diffracted luminous flux using the following expression:

R_{N/O}=I_{NG}max/I_{OK}min

In S907, the optical intensity measuring processor 83 calculates a sum Isum of the optical intensities of the first and second diffracted luminous fluxes using the following expression:

Isum=I_{OK}sum+I_{NG}sum

In S908, the optical intensity measuring processor 83 saves the following calculated values in the data managing server 93:
Sum Isum of optical intensities of first and second diffracted luminous fluxes
Optical intensity I_{OK}min of first minimum diffracted luminous flux
Optical intensity ratio R_{N/O} of optical intensity I_{NG}max of second maximum diffracted luminous flux to optical intensity I_{OK}min of first minimum diffracted luminous flux

### 3.4 Processes Carried Out by Laser Processing Processor 53

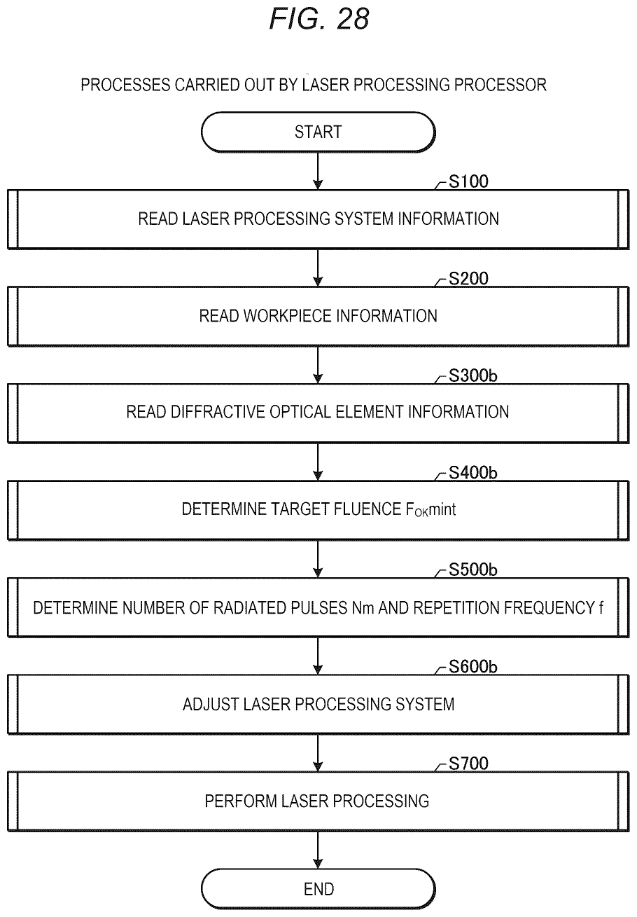

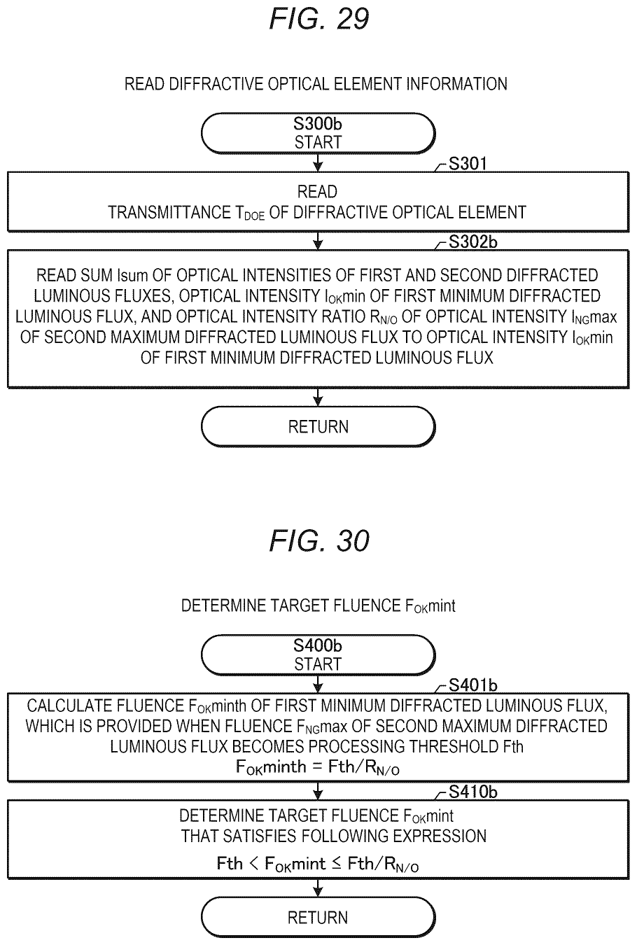

FIG. 28 is a flowchart showing laser processing processes in the second embodiment. Out of the laser processing processes in the second embodiment, the processes in S300b, S400b, S500b, and S600b differ from the corresponding processes in the first embodiment. The different processes will be described below in detail with reference to FIGS. 29 to 32.

### 3.4.1 Read Diffractive Optical Element Information

FIG. 29 is a flowchart showing the process of reading information on the diffractive optical element 63 in detail. The processes shown in FIG. 29 correspond to the subroutine labeled with S300b in FIG. 28.

In S301, the laser processing processor 53 reads the transmittance T_{DOE} of the diffractive optical element 63. This point is the same as that in Comparative Example.

In S302b, the laser processing processor 53 reads the following information calculated in FIG. 27:
Sum Isum of optical intensities of first and second diffracted luminous fluxes
Optical intensity I_{OK}min of first minimum diffracted luminous flux
Optical intensity ratio R_{N/O} of optical intensity I_{NG}max of second maximum diffracted luminous flux to optical intensity I_{OK}min of first minimum diffracted luminous flux

The sum Isum of the optical intensities of the first and second diffracted luminous fluxes and the optical intensity I_{OK}min of the first minimum diffracted luminous flux are used in S603b, which will be described with reference to FIG. 32. The optical intensity ratio R_{N/O} is used in S401b, which will be described with reference to FIG. 30.

After S302b, the laser processing processor 53 terminates the processes in the present flowchart, and returns to the processes shown in FIG. 28.

### 3.4.2 Determine Target Fluence

FIG. 30 is a flowchart showing the process of determining the target fluence F_{OK}mint of the first minimum diffracted luminous flux in detail. The processes shown in FIG. 30 correspond to the subroutine labeled with S400b in FIG. 28.

In S401b, the laser processing processor 53 calculates a fluence F_{OK}minth of the first minimum diffracted luminous flux, which is provided when the fluence F_{NG}max of the second maximum diffracted luminous flux becomes the processing threshold Fth, using the following expression:

F_{OK}minth=Fth/R_{N/O}

In S410b, the laser processing processor 53 determines the target fluence F_{OK}mint that satisfies the following expression:

Fth<F_{OK}mint≤Fth/R_{N/O}

The target fluence F_{OK}mint may be set at Fth/R_{N/O}, which is the upper limit. This can maximize the efficiency of the laser processing while suppressing the processing performed at the non-processing points that require no processing. The target fluence F_{OK}mint may instead be set at the average of Fth and Fth/R_{N/O}. In this case, even when the pulse energy of the pulse laser light Out unexpectedly varies, a situation in which the processing is performed at the non-processing points or a situation in which sufficient processing is not performed at the processing points can be avoided.

After S410b, the laser processing processor 53 terminates the processes in the present flowchart, and returns to the processes shown in FIG. 28.

### 3.4.3 Determine Number of Radiated Pulses Nm and Repetition Frequency f

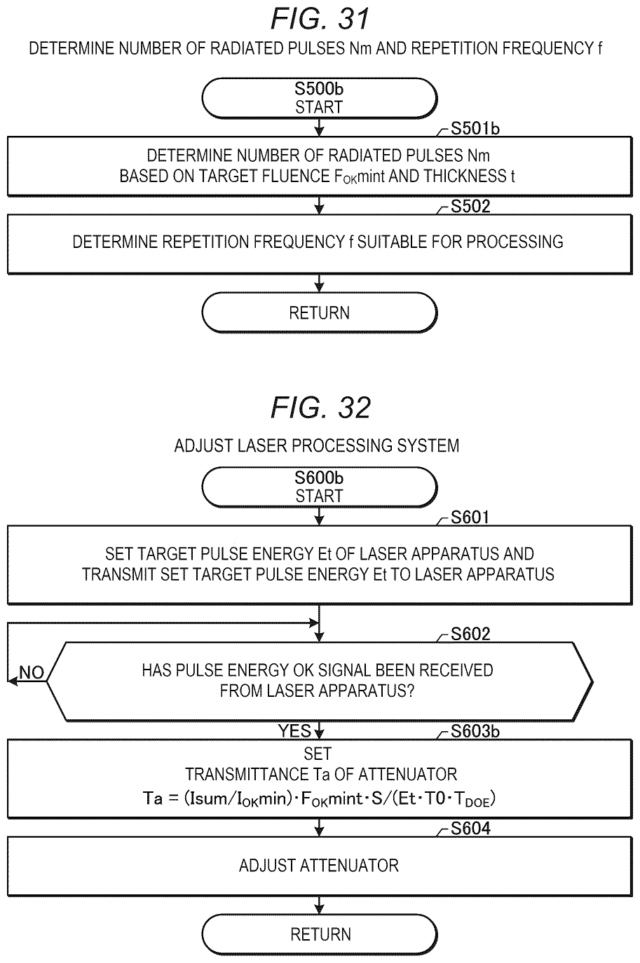

FIG. 31 is a flowchart showing details of the process of determining the number of radiated pulses Nm and the repetition frequency f in the single laser processing. The processes shown in FIG. 31 correspond to the subroutine labeled with S500b in FIG. 28.

In S501b, the laser processing processor 53 determines the number of radiated pulses Nm based on the target fluence F_{OK}mint of the first minimum diffracted luminous flux and the thickness t. The first minimum diffracted luminous flux and the first maximum diffracted luminous flux differ in fluence from each other, and therefore give different processing speeds. Determining the number of radiated pulses Nm based on the target fluence F_{OK}mint of the first minimum diffracted luminous flux, which performs the laser processing at the slowest processing speed, holes having a sufficient depth can be formed at all the processing points. For example, when the depth of the hole formed at the processing point on which the first minimum diffracted luminous flux is incident is equal to the thickness t, through holes can be formed at all the processing points.

In S502, the laser processing processor 53 determines the repetition frequency f suitable for the processing. This point is the same as that in Comparative Example.

After S502, the laser processing processor 53 terminates the processes in the present flowchart, and returns to the processes shown in FIG. 28.

### 3.4.4 Adjust Laser Processing System

FIG. 32 is a flowchart showing details of the process of adjusting the laser processing system based on the target fluence F_{OK}mint. The processes shown in FIG. 32 correspond to the subroutine labeled with S600b in FIG. 28.

The processes shown in FIG. 32 differ from those in the first embodiment shown in FIG. 23 in terms of expression for setting the transmittance Ta of the attenuator 52 in S603b. The energy per pulse of the first minimum diffracted luminous flux is expressed by the following equality:

(I_{OK}min/Isum)·Et·Ta·T0·T_{DOE}=F_{OK}mint·S

The transmittance Ta of the attenuator 52 is therefore calculated by the following expression:

Ta=F_{OK}mint·S·(Isum/I_{OK}min)/(Et·T0·T_{DOE})

The processes shown in FIG. 32 are otherwise the same as the processes shown in FIG. 23.

### 3.5 Effects

(3) According to the second embodiment, the first diffracted luminous fluxes vary in terms of the fluence F_{OK}m, and the second diffracted luminous fluxes vary in terms of the fluence F_{NG}m. The laser processing processor 53 controls the adjustment mechanism in such a way that the following conditions are satisfied: (a) The fluence F_{OK}min of the first minimum diffracted luminous flux, which is the minimum of the fluences F_{OK}m, out of the first diffracted luminous fluxes is greater than the processing threshold Fth. (b) The fluence F_{NG}max of the second maximum diffracted luminous flux, which is the maximum of the fluences F_{NG}m, out of the second diffracted luminous fluxes is smaller than or equal to the processing threshold Fth.

Under the conditions described above, even when the plural diffracted luminous fluxes vary in terms of fluence, satisfying the condition on the fluence F_{OK}min of the first minimum diffracted luminous flux allows the fluences F_{OK}m of the first luminous fluxes radiated to the multiple processing points to be greater than the processing threshold Fth. Furthermore, satisfying the condition on the fluence F_{NG}max of the second maximum diffracted luminous flux allows the fluences F_{NG}m of the second diffracted luminous fluxes radiated to the multiple non-processing points to be smaller than or equal to the processing threshold Fth. Necessary processing can therefore be performed with unnecessary processing suppressed.

(4) According to the second embodiment, the laser processing processor 53 controls the adjustment mechanism such as the attenuator 52 by setting the target fluence F_{OK}mint, which is the target value of the fluence F_{OK}min of the first minimum diffracted luminous flux, as follows: (a) The target fluence F_{OK}mint is greater than the processing threshold Fth. (b) The target fluence F_{OK}mint is smaller than or equal to the value Fth/R_{N/O}, which is a result of division of the processing threshold Fth by the optical intensity ratio R_{N/O}, which is a result of division of the optical intensity I_{NG}max of the second maximum diffracted luminous flux by the optical intensity I_{OK}min of the first minimum diffracted luminous flux.

With the two conditions satisfied, even when the multiple diffracted luminous fluxes vary in terms of fluence, setting the target fluence F_{OK}mint of the first minimum diffracted luminous flux allows the fluences F_{OK}m of the first luminous fluxes radiated to the multiple processing points to fall within a desired range. Furthermore, when the target fluence F_{OK}mint of the first minimum diffracted luminous flux is set, the optical intensity ratio R_{N/O} can be used to cause the fluences F_{NG}m of the second diffracted luminous fluxes radiated to the multiple non-processing points to fall within a desired range.

(5) According to the second embodiment, the laser processing processor 53 calculates parameters such as the transmittance Ta of the attenuator 52, which adjusts the pulse energy of the pulse laser light Out to be incident on the diffractive optical element 63, and controls the adjustment mechanism such as the attenuator 52. The parameters are calculated based on the ratio between the sum Isum of the optical intensities of the first and second diffracted luminous fluxes and the optical intensity I_{OK}min of the first minimum diffracted luminous flux, and the target fluence F_{OK}mint.

In the thus configured second embodiment, even when the multiple first diffracted luminous fluxes vary in terms of fluence, or when part of the pulse energy of the pulse laser light Out is discarded as the energy of the second diffracted luminous fluxes, the ratio of the sum Isum of the optical intensities of the first and second diffracted luminous fluxes and the optical intensity I_{OK}min of the first minimum diffracted luminous flux can be used to set the target fluence F_{OK}mint of the first minimum diffracted luminous flux.

The second embodiment is otherwise the same as the first embodiment.

4. Laser Processing System in Consideration of Variation in Pulse Energy of Pulse Laser Light Output from Laser Apparatus

### 4.1 Concept

### 4.1.1 Fluences of First and Second Diffracted Luminous Fluxes

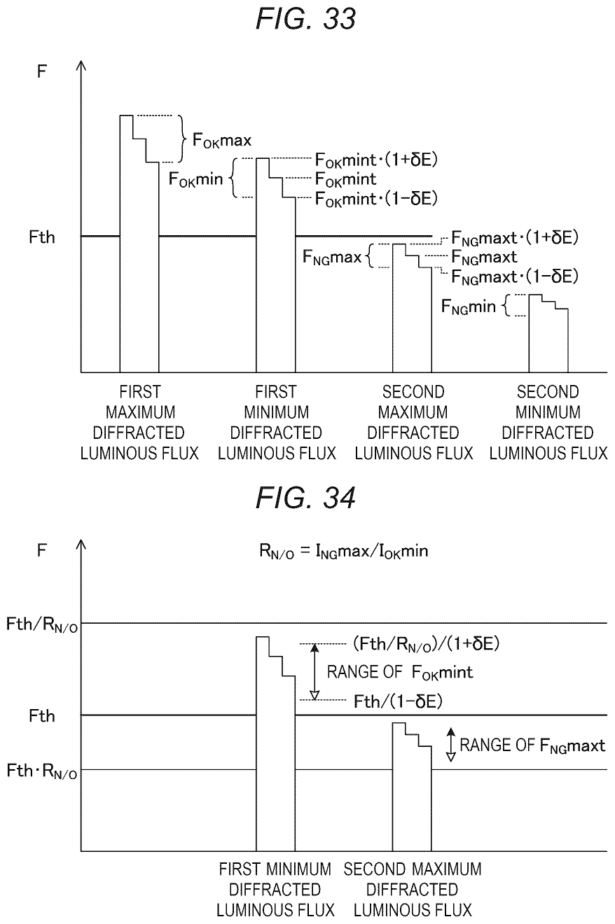

FIG. 33 is a bar graph showing an example of the result of control in a variation of the second embodiment. In the variation of the second embodiment, variation δE of the pulse energy of the pulse laser light Out output from the laser apparatus 1 is taken into account. When the pulse energy of the pulse laser light Out varies, the fluences of the first maximum diffracted luminous flux, the first minimum diffracted luminous flux, the second maximum diffracted luminous flux, and the second minimum diffracted luminous flux all vary based on the same pulse energy variation δE. The pulse energy variation δE is calculated from the standard deviation and the average of the pulse energy values of the multiple pulses contained in the pulse laser light Out. For example, the pulse energy variation δE is a value as a result of division of the standard deviation multiplied by one, two, or three by the average.

In FIG. 33, the horizontal axis shows the first maximum diffracted luminous flux, the first minimum diffracted luminous flux, the second maximum diffracted luminous flux, and the second minimum diffracted luminous flux, and the vertical axis represents the fluence F of each of the diffracted luminous fluxes at the surface of the workpiece SUB. The fluence F of each of the diffracted luminous fluxes varies based on the pulse energy variation δE as described below.

The range over which the fluence F_{OK}min of the first minimum diffracted luminous flux varies based on the pulse energy variation δE is called a first variation range. The first variation range can be expressed by the following expression using the target fluence F_{OK}mint of the first minimum diffracted luminous flux:

F_{OK}mint·(1−δE)≤F_{OK}min≤F_{OK}mint·(1+δE)

The range over which the fluence F_{NG}max of the second maximum diffracted luminous flux varies based on the pulse energy variation δE is called a second variation range. The second variation range can be expressed by the following expression using a target fluence F_{NG}maxt of the second maximum diffracted luminous flux:

F_{NG}maxt·(1−δE)≤F_{NG}max≤F_{NG}maxt·(1+δE)

The target fluence F_{NG}maxt of the second maximum diffracted luminous flux is obtained by multiplying the target fluence F_{OK}mint of the first minimum diffracted luminous flux by the optical intensity ratio R_{N/O}. The target fluence F_{NG}maxt of the second maximum diffracted luminous flux is a name for convenience to compare with the target fluence F_{OK}mint of the first minimum diffracted luminous flux, and the value of the target fluence F_{NG}maxt may not be used as the fluence target value.

The fluence F_{OK}max of the first maximum diffracted luminous flux and the fluence F_{NG}min of the second minimum diffracted luminous flux similarly vary based on the pulse energy variation δE.

In the variation of the second embodiment, the laser processing processor 53 controls the adjustment mechanism such as the attenuator 52 in such a way that the minimum value F_{OK}mint·(1−δE) in the first variation range of the fluence F_{OK}min of the first minimum diffracted luminous flux is greater than the processing threshold Fth and the maximum value F_{NG}maxt·(1+δE) in the second variation range of the fluence F_{NG}max of the second maximum diffracted luminous flux is smaller than or equal to the processing threshold Fth.

### 4.1.2 Set Target Fluence F_{OK}mint

FIG. 34 is a bar graph showing an example of the target fluence F_{OK}mint of the first minimum diffracted luminous flux that is set in the variation of the second embodiment. In FIG. 34, the horizontal axis shows the first minimum diffracted luminous flux and the second maximum diffracted luminous flux, and the vertical axis represents the fluence F of each of the diffracted luminous fluxes at the surface of the workpiece SUB.

### 4.1.2.1 Lower Limit of Target Fluence F_{OK}mint

The target fluence F_{OK}mint is set at a value that causes the minimum value F_{OK}mint·(1−δE) in the first variation range of the fluence F_{OK}min of the first minimum diffracted luminous flux to be a value greater than the processing threshold Fth. The following relationship is therefore given:

Fth<F_{OK}mint·(1−δE)

The following relationship indicating the lower limit of the target fluence F_{OK}mint is derived from the above inequality.

Fth/(1−δE)<F_{OK}mint

The left-hand side of the above expression, Fth/(1−δE), corresponds to a value as a result of addition of Fth·δE/(1−δE) to the processing threshold Fth, as expressed by the following expression:

Fth/(1−δE)=Fth+Fth·δE/(1−δE)

Fth·δE/(1−δE) corresponds to the first variation range in the present disclosure.

Setting the lower limit of the target fluence F_{OK}mint of the first minimum diffracted luminous flux as described above causes the minimum value F_{OK}mint·(1−δE) in the first variation range of the fluence F_{OK}min of the first minimum diffracted luminous flux to be a value greater than the processing threshold Fth. The fluences of the first diffracted luminous fluxes including the fluence F_{OK}max of the first maximum diffracted luminous flux, which are all greater than or equal to the minimum value F_{OK}mint·(1−δE) in the first variation range of the fluence F_{OK}min of the first minimum diffracted luminous flux, are also greater than the processing threshold Fth.

### 4.1.2.2 Upper Limit of Target Fluence F_{OK}mint

The target fluence F_{OK}mint is set at a value that causes the maximum value F_{NG}maxt·(1+δE) in the second variation range of the fluence F_{NG}max of the second maximum diffracted luminous flux to be a value smaller than or equal to the processing threshold Fth. The following relationship is therefore given:

F_{NG}maxt·(1+δE)≤Fth

The target fluence F_{NG}maxt is obtained by multiplying the target fluence F_{OK}mint of the first minimum diffracted luminous flux by the optical intensity ratio R_{N/O}. The following relationship indicating the upper limit of the target fluence F_{OK}mint is then derived from the above inequality.

F_{OK}mint≤(Fth/R_{N/O})/(1+δE)

The right-hand side of the above expression, (Fth/R_{N/O})/(1+δE), corresponds to a value as a result of subtraction of (Fth/R_{N/O})·δE/(1+δE) from the value Fth/R_{N/O} as a result of division of the processing threshold Fth by the optical intensity ratio R_{N/O}, as expressed by the following expression:

(Fth/R_{N/O})/(1+δE)=Fth/R_{N/O}−(Fth/R_{N/O})·δE/(1+δE)

(Fth/R_{N/O})·δE/(1+δE) corresponds to the second variation range in the present disclosure.

Setting the upper limit of the target fluence F_{OK}mint of the first minimum diffracted luminous flux as described above causes the maximum value F_{NG}maxt·(1+δE) in the second variation range of the fluence F_{NG}max of the second maximum diffracted luminous flux to be a value smaller than or equal to the processing threshold Fth. The fluences of the second diffracted luminous fluxes including the fluence F_{NG}min of the second minimum diffracted luminous flux, which are all smaller than or equal to the maximum value F_{NG}maxt·(1+δE) in the second variation range of the fluence F_{NG}max of the second maximum diffracted luminous flux, are also smaller than or equal to the processing threshold Fth. It is noted that when the minimum value F_{OK}mint·(1−δE) in the first variation range of the fluence F_{OK}min of the first minimum diffracted luminous flux is set at a value greater than the processing threshold Fth, setting the target fluence F_{OK}mint at a value greater than Fth/(1−δE) causes the minimum value F_{NG}maxt·(1−δE) in the second variation range of the fluence F_{NG}max of the second maximum diffracted luminous flux to be a value greater than the value Fth·R_{N/O}.

### 4.1.2.3 Range of Target Fluence F_{OK}mint

FIG. 34 and the description thereof show that setting the target fluence F_{OK}mint at a value that falls within the range shown below causes the entire first variation range of the fluences of the first diffracted luminous fluxes to be a value greater than the processing threshold Fth, and the entire second variation range of the fluences of the second diffracted luminous fluxes to be a value smaller than or equal to the processing threshold Fth.

Fth/(1−δE)<F_{OK}mint≤(Fth/R_{N/O})/(1+δE)

### 4.2 Configuration of Laser Processing System

The configuration of the laser processing system according to the variation of the second embodiment is the same as the configuration in Comparative Example described with reference to FIG. 1.

### 4.3 Processes Carried Out by Laser Processing Processor 53

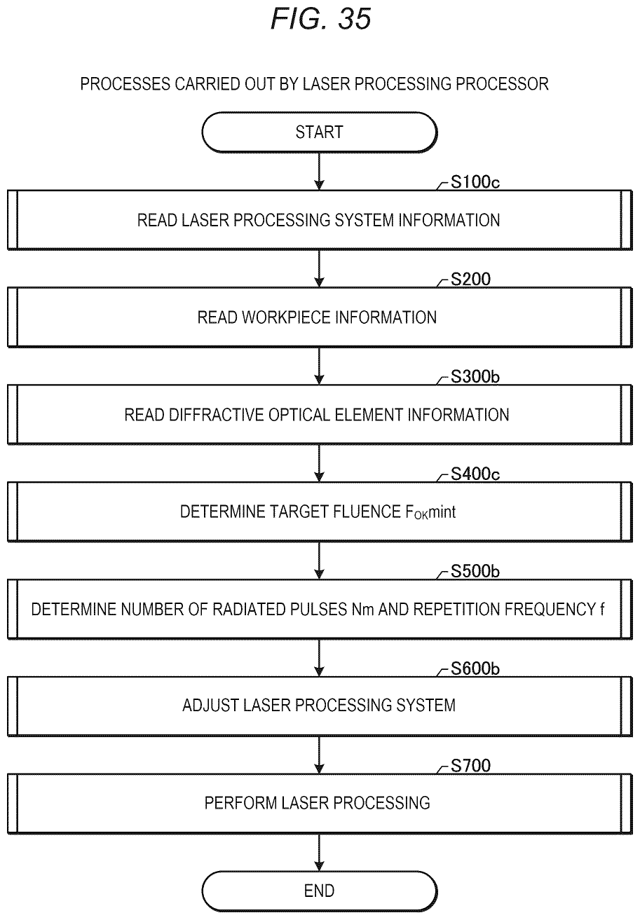

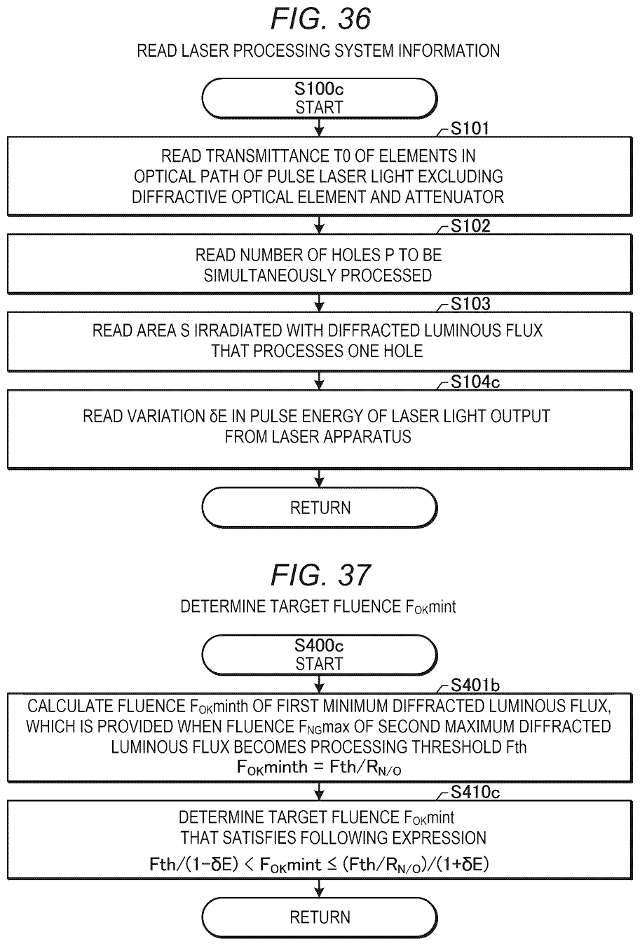

FIG. 35 is a flowchart showing laser processing processes in the variation of the second embodiment. Out of the laser processing processes in the variation of the second embodiment, the processes in S100c and S400c differ from the corresponding processes in the second embodiment. The different processes will be described below in detail with reference to FIGS. 36 and 37.

### 4.3.1 Read Laser Processing System Information

FIG. 36 is a flowchart showing the process of reading information on the laser processing system in detail. The processes shown in FIG. 36 correspond to the subroutine labeled with S100c in FIG. 35.

In S101 to S103, the laser processing processor 53 reads the transmittance TO, the number of holes P, and the irradiated area S. This point is the same as that in Comparative Example.

In S104c, the laser processing processor 53 reads the pulse energy variation δE. The pulse energy variation δE is used in S410c, which will be described with reference to FIG. 37.

After S104c, the laser processing processor 53 terminates the processes in the present flowchart, and returns to the processes shown in FIG. 35.

### 4.3.2 Determine Target Fluence

FIG. 37 is a flowchart showing the process of determining the target fluence F_{OK}mint of the first minimum diffracted luminous flux in detail. The processes shown in FIG. 37 correspond to the subroutine labeled with S400c in FIG. 35.

In S401b, the laser processing processor 53 calculates the fluence F_{OK}minth of the first minimum diffracted luminous flux, which is provided when the fluence F_{NG}max of the second maximum diffracted luminous flux becomes the processing threshold Fth. This point is the same as that in the second embodiment.

In S410c, the laser processing processor 53 determines the target fluence F_{OK}mint that satisfies the following expression:

Fth/(1−δE)<F_{OK}mint≤(Fth/R_{N/O})/(1+δE)

The target fluence F_{OK}mint may be set at (Fth/R_{N/O})/(1+δE), which is the upper limit. This can maximize the efficiency of the laser processing while suppressing the processing performed at the non-processing points that require no processing. The target fluence F_{OK}mint may instead be set at the average of Fth/(1−δE) and (Fth/R_{N/O})/(1+δE). In this case, even when the pulse energy of the pulse laser light Out unexpectedly varies, a situation in which the processing is performed at the non-processing points or a situation in which sufficient processing is not performed at the processing points that require the processing can be avoided.

After S410c, the laser processing processor 53 terminates the processes in the present flowchart, and returns to the processes shown in FIG. 35.

### 4.4 Effects

(6) According to the variation of the second embodiment, the first diffracted luminous fluxes vary in terms of the fluence F_{OK}m, and the second diffracted luminous fluxes vary in terms of the fluence F_{NG}m. The laser processing processor 53 controls the adjustment mechanism in such a way that the following conditions are satisfied: (a) The minimum value F_{OK}mint·(1−δE) in the first variation range of the fluence F_{OK}min of the first minimum diffracted luminous flux having the minimum of the fluences F_{OK}m out of the first diffracted luminous fluxes, the first variation range derived based on the variation δE of the pulse energy of the pulse laser light Out incident on the diffractive optical element 63, is greater than the processing threshold Fth. (b) The maximum value F_{NG}maxt·(1+δE) in the second variation range of the fluence F_{NG}max of the second maximum diffracted luminous flux having the maximum of the fluences F_{NG}m out of the second diffracted luminous fluxes, the second variation range derived based on the pulse energy variation δE, is smaller than or equal to the processing threshold Fth.

With the conditions described above satisfied, the entire variation range of the fluences F_{OK}m of the first diffracted luminous fluxes radiated to the multiple processing points can be greater than the processing threshold Fth not only when the multiple diffracted luminous fluxes vary in terms of fluence but also when the pulse laser light Out contains the pulse energy variation δE. In addition, the entire variation range of the fluences F_{NG}m of the second diffracted luminous fluxes radiated to the multiple non-processing points can be smaller than or equal to the processing threshold Fth. Necessary processing can therefore be performed with unnecessary processing suppressed.

(7) According to the variation of the second embodiment, the laser processing processor 53 controls the adjustment mechanism such as the attenuator 52 by setting the target fluence F_{OK}mint, which is the target value of the fluence F_{OK}min of the first minimum diffracted luminous flux, as follows: (a) The target fluence F_{OK}mint is greater than the value Fth/(1−δE) as a result of addition of the first variation range Fth 6E/(1−δE), which indicates the pulse energy variation δE, to the processing threshold Fth. (b) The target fluence F_{OK}mint is smaller than or equal to the value (Fth/R_{N/O})/(1+δE), which is a result of subtraction of the second variation range (Fth/R_{N/O})·δE/(1+δE) indicating the pulse energy variation δE from the value Fth/R_{N/O}, which is a result of division of the processing threshold Fth by the optical intensity ratio R_{N/O}, which is a result of division of the optical intensity I_{NG}max of the second maximum diffracted luminous flux by the optical intensity I_{OK}min of the first minimum diffracted luminous flux.

With the conditions described above satisfied, the entire variation range of the fluences F_{OK}m of the first diffracted luminous fluxes radiated to the multiple processing points are allowed to fall within a desired range not only when the multiple diffracted luminous fluxes vary in terms of fluence but also when the pulse laser light Out contains the pulse energy variation δE. Furthermore, when the target fluence F_{OK}mint of the first minimum diffracted luminous flux is set, the optical intensity ratio R_{N/O} can be used to cause the entire variation range of the fluences F_{NG}m of the second diffracted luminous fluxes radiated to the multiple non-processing points to fall within a desired range.

The variation of the second embodiment is otherwise the same as the second embodiment.

### 5. Laser Processing System in Consideration of Fluence Upper Limit

### 5.1 Concept

### 5.1.1 Fluences of First and Second Diffracted Luminous Fluxes

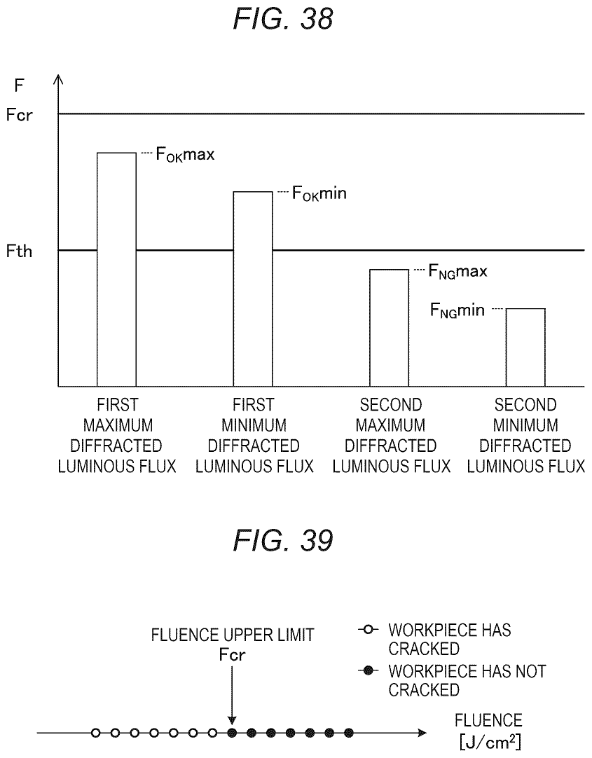

FIG. 38 is a bar graph showing an example of the result of control in a third embodiment. In the third embodiment, consideration is given to an upper limit of the fluences of the first diffracted luminous fluxes focused at the processing points. For example, when the fluence is too high, the workpiece SUB may unintendedly crack.

In FIG. 38, the horizontal axis shows the first maximum diffracted luminous flux, the first minimum diffracted luminous flux, the second maximum diffracted luminous flux, and the second minimum diffracted luminous flux, and the vertical axis represents the fluence F of each of the diffracted luminous fluxes at the surface of the workpiece SUB. The laser processing processor 53 controls the adjustment mechanism such as the attenuator 52 in such a way that the fluence F_{OK}min of the first minimum diffracted luminous flux is greater than the processing threshold Fth and the fluence F_{NG}max of the second maximum diffracted luminous flux is smaller than or equal to the processing threshold Fth, as in the second embodiment. Furthermore, in the third embodiment, the laser processing processor 53 controls the adjustment mechanism such as the attenuator 52 in such a way that the fluence F_{OK}max of the first maximum diffracted luminous flux is smaller than or equal to a fluence upper limit Fcr. That is, the adjustment mechanism is so controlled that the following three conditions are satisfied at the same time.

F_{OK}min>Fth

F_{NG}max≤Fth

F_{OK}max≤Fcr

FIG. 39 is a graph showing an example of the definition of the fluence upper limit Fcr. In FIG. 39, the horizontal axis represents the fluence of the diffracted luminous fluxes. Multiple workpieces SUB are irradiated with the diffracted luminous fluxes having different fluences, and whether the workpieces SUB crack is generated. The fluence upper limit Fcr is the fluence of the diffracted luminous flux having the minimum fluence out of the crack generating diffracted luminous fluxes. The workpiece SUB irradiated with the diffracted luminous fluxes having a fluence smaller than the fluence upper limit Fcr is unlikely to crack, whereas the workpiece SUB irradiated with the diffracted luminous fluxes having a fluence greater than or equal to the fluence upper limit Fcr is likely to crack.

### 5.1.2 Set Target Fluence F_{OK}mint

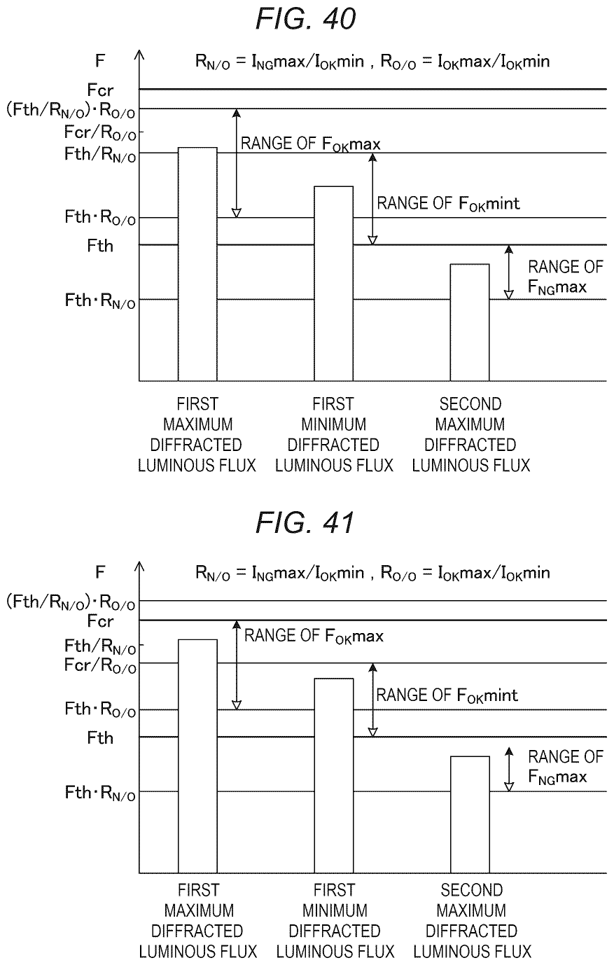

FIGS. 40 and 41 are bar graphs showing examples of the target fluence F_{OK}mint of the first minimum diffracted luminous flux that is set in the third embodiment. In FIGS. 40 and 41, the horizontal axis shows the first maximum diffracted luminous flux, the first minimum diffracted luminous flux, and the second maximum diffracted luminous flux, and the vertical axis represents the fluence F of each of the diffracted luminous fluxes at the surface of the workpiece SUB.

### 5.1.2.1 Lower Limit of Target Fluence F_{OK}mint

The target fluence F_{OK}mint is set at a value greater than the processing threshold Fth, as in the second embodiment. As a result, the fluence F_{OK}min of the first minimum diffracted luminous flux is greater than the processing threshold Fth. The fluences of the first diffracted luminous fluxes including the fluence F_{OK}max of the first maximum diffracted luminous flux, which are all greater than or equal to the fluence F_{OK}min of the first minimum diffracted luminous flux, are also greater than the processing threshold Fth.

### 5.1.2.2 Upper Limit (1) of Target Fluence F_{OK}mint

The target fluence F_{OK}mint is set at a value smaller than or equal to the value Fth/R_{N/O} as a result of division of the processing threshold Fth by the optical intensity ratio R_{N/O}, as in the second embodiment. Setting the target fluence F_{OK}mint at a value smaller than or equal to the value Fth/R_{N/O} causes the fluence F_{NG}max of the second maximum diffracted luminous flux to be a value smaller than or equal to the processing threshold Fth. The fluences of the second diffracted luminous fluxes including the fluence F_{NG}min of the second minimum diffracted luminous flux, which are all smaller than or equal to the fluence F_{NG}max of the second maximum diffracted luminous flux, are also smaller than or equal to the processing threshold Fth. It is noted that setting the target fluence F_{OK}mint at a value greater than the processing threshold Fth causes the fluence F_{NG}max of the second maximum diffracted luminous flux to be a value greater than a value Fth R_{N/O}.

### 5.1.2.3 Upper Limit (2) of Target Fluence F_{OK}mint

An optical intensity ratio R_{O/O} is assumed to be a value as a result of division of an optical intensity I_{OK}max of the first maximum diffracted luminous flux at the surface of the workpiece SUB by the optical intensity I_{OK}min of the first minimum diffracted luminous flux at the surface of the workpiece SUB, as expressed by the following expression:

R_{O/O}=I_{OK}max/I_{OK}min

A fluence F_{OK}mincr of the first minimum diffracted luminous flux that is provided when the fluence F_{OK}max of the first maximum diffracted luminous flux becomes the fluence upper limit Fcr is given by the following expression:

F_{OK}mincr=Fcr/R_{O/O}

The target fluence F_{OK}mint is set at a value smaller than or equal to the value Fcr/R_{O/O} as a result of division of the fluence upper limit Fcr by the optical intensity ratio R_{O/O}. Setting the target fluence F_{OK}mint at a value smaller than or equal to the value Fcr/R_{O/O} causes the fluence F_{OK}max of the first maximum diffracted luminous flux to be a value smaller than or equal to the fluence upper limit Fcr. The fluences of the first diffracted luminous fluxes including the fluence F_{OK}min of the first minimum diffracted luminous flux, which are all smaller than or equal to the fluence F_{OK}max of the first maximum diffracted luminous flux, are also smaller than or equal to the fluence upper limit Fcr.

### 5.1.2.4 Range of Target Fluence F_{OK}mint

In the third embodiment, the target fluence F_{OK}mint has two upper limits, as described above. That is, the target fluence F_{OK}mint is set at a value smaller than or equal to the value Fth/R_{N/O} and smaller than or equal to the value Fcr/R_{O/O}.

When the value Fcr/R_{O/O} is greater than the value Fth/R_{N/O}, that is, when the fluence upper limit Fcr is greater than the value (Fth/R_{N/O})·R_{O/O}, making the target fluence F_{OK}mint smaller than or equal to the value Fth/R_{N/O} eliminates the need for consideration of the value Fcr/R_{O/O} (see FIG. 40).

In this case, setting the target fluence F_{OK}mint at a value that falls within the range shown below causes the fluence F_{OK}min of the first minimum diffracted luminous flux to be a value greater than the processing threshold Fth, the fluence F_{OK}max of the first maximum diffracted luminous flux to be a value smaller than or equal to the fluence upper limit Fcr, and the fluence F_{NG}max of the second maximum diffracted luminous flux to be a value smaller than or equal to the processing threshold Fth, as in the second embodiment.

Fth<F_{OK}mint≤Fth/R_{N/O}

In other words, when the fluence upper limit Fcr is greater than the value (Fth/R_{N/O})·R_{O/O}, the following two conditions only need to be satisfied at the same time.

F_{OK}min>Fth

F_{NG}max≤Fth

When the value Fcr/R_{O/O} is smaller than the value Fth/R_{N/O}, that is, when the fluence upper limit Fcr is smaller than the value (Fth/R_{N/O})·R_{O/O}, making the target fluence F_{OK}mint smaller than or equal to the value Fcr/R_{O/O} eliminates the need for consideration of the value Fth/R_{N/O} (see FIG. 41). The value (Fth/R_{N/O})·R_{O/O} corresponds to a fluence F_{OK}maxth of the first maximum diffracted luminous flux provided when the fluence F_{NG}max of the second maximum diffracted luminous flux becomes the processing threshold Fth.

In this case, setting the target fluence F_{OK}mint at a value that falls within the range shown below causes the fluence F_{OK}min of the first minimum diffracted luminous flux to be a value greater than the processing threshold Fth, the fluence F_{OK}max of the first maximum diffracted luminous flux to be a value smaller than or equal to the fluence upper limit Fcr, and the fluence F_{NG}max of the second maximum diffracted luminous flux to be a value smaller than or equal to the processing threshold Fth.

Fth<F_{OK}mint≤Fcr/R_{O/O}

In other words, when the fluence upper limit Fcr is smaller than the value (Fth/R_{N/O})·R_{O/O}, the following two conditions only need to be satisfied at the same time.

F_{OK}min>Fth

F_{OK}max≤Fcr

### 5.2 Configuration of Laser Processing System

The configuration of the laser processing system according to the third embodiment is the same as the configuration in Comparative Example described with reference to FIG. 1.

### 5.3 Measure Diffractive Optical Element Information

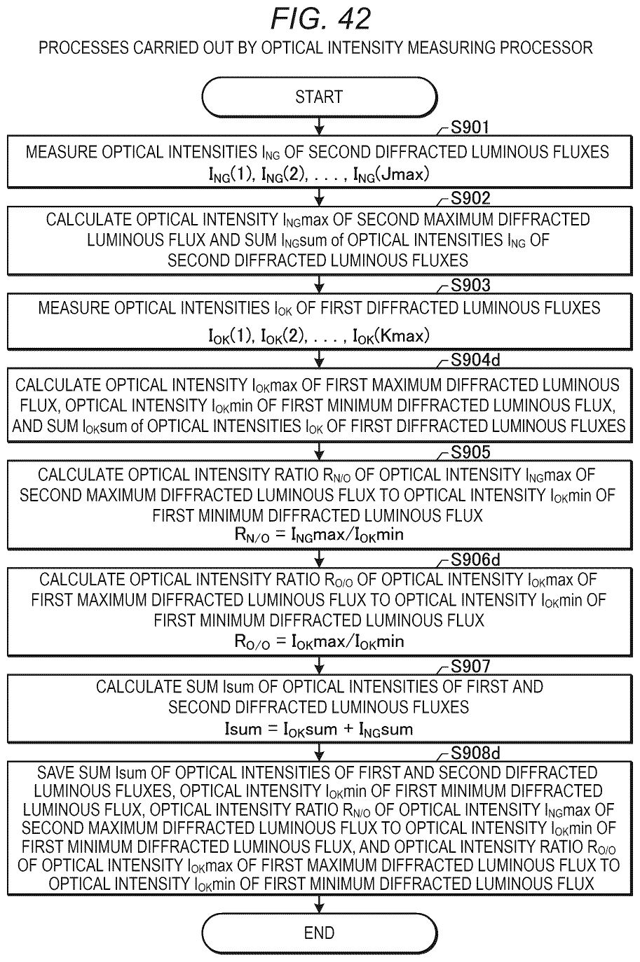

FIG. 42 is a flowchart showing the process of measuring the optical intensities in the third embodiment. The configuration of the measurement system that measures the information on the diffractive optical element 63 in the third embodiment is the same as that in the second embodiment described with reference to FIG. 26. Out of the processes shown in FIG. 42, the processes in S904d and S908d differ from corresponding processes in the second embodiment, and the process in S906d is added.

In S904d, the optical intensity measuring processor 83 calculates the following values:
Optical intensity I_{OK}max of first maximum diffracted luminous flux
Optical intensity I_{OK}min of first minimum diffracted luminous flux
Sum I_{OK}sum of optical intensities I_{OK} of first diffracted luminous fluxes

The optical intensity I_{OK}max of the first maximum diffracted luminous flux is the maximum of the optical intensities I_{OK} of the first diffracted luminous fluxes.

In S906d after S905 but before S907, the optical intensity measuring processor 83 calculates the optical intensity ratio R_{O/O} of the optical intensity I_{OK}max of the first maximum diffracted luminous flux to the optical intensity I_{OK}min of the first minimum diffracted luminous flux using the following expression:

R_{O/O}=I_{OK}max/I_{OK}min

In S908d, the optical intensity measuring processor 83 saves the calculated values below in the data managing server 93.
Sum Isum of optical intensities of first and second diffracted luminous fluxes
Optical intensity I_{OK}min of first minimum diffracted luminous flux
Optical intensity ratio R_{N/O} of optical intensity I_{NG}max of second maximum diffracted luminous flux to optical intensity I_{OK}min of first minimum diffracted luminous flux
Optical intensity ratio R_{O/O} of optical intensity I_{OK}max of first maximum diffracted luminous flux to optical intensity I_{OK}min of first minimum diffracted luminous flux

### 5.4 Processes Carried Out by Laser Processing Processor 53

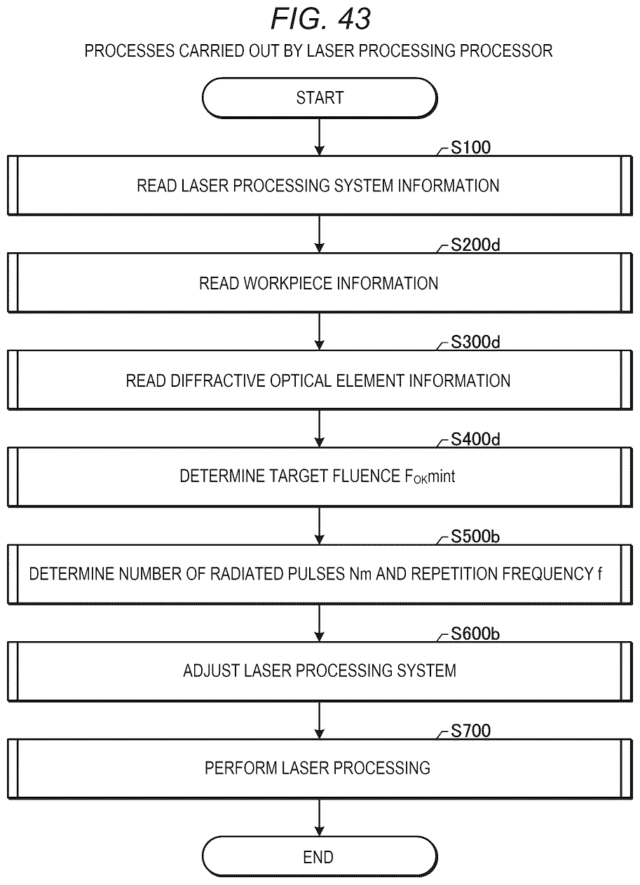

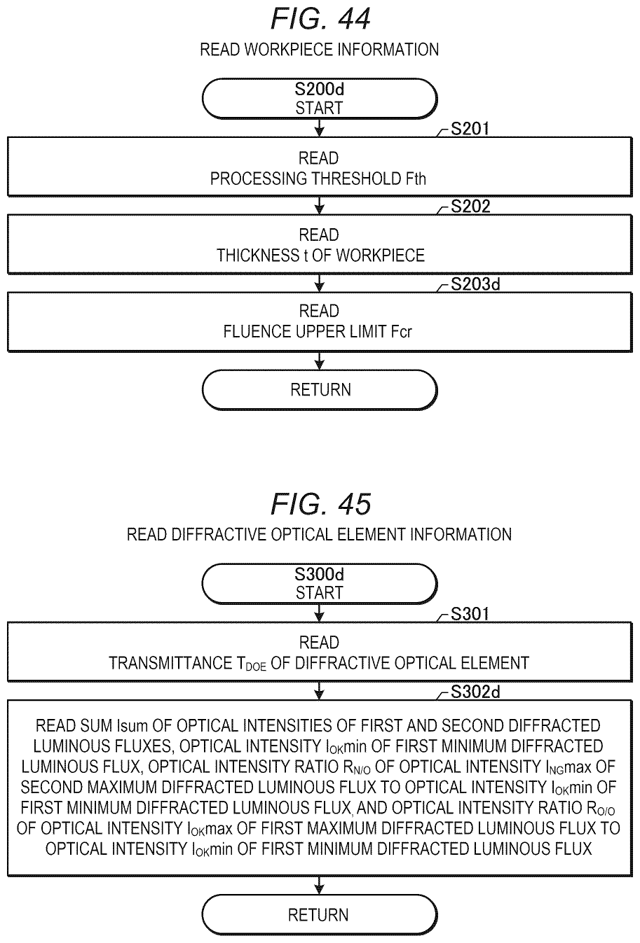

FIG. 43 is a flowchart showing laser processing processes in the third embodiment. Out of the laser processing processes in the third embodiment, the processes in S200d, S300d, and S400d differ from the corresponding processes in the second embodiment. The different processes will be described below in detail with reference to FIGS. 44 to 46.

### 5.4.1 Read Workpiece Information

FIG. 44 is a flowchart showing the process of reading information on the workpiece SUB in detail. The processes shown in FIG. 44 correspond to the subroutine labeled with S200d in FIG. 43.

In S201 and S202, the laser processing processor 53 reads the processing threshold Fth and the thickness t. This point is the same as that in Comparative Example.

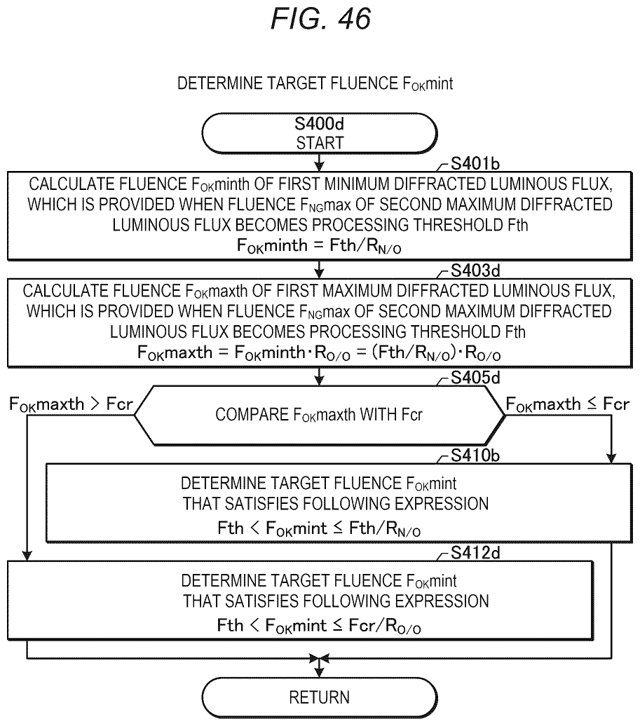

In S203d, the laser processing processor 53 reads the fluence upper limit Fcr. The fluence upper limit Fcr is used in S405d and S412d, which will be described with reference to FIG. 46.

After S203d, the laser processing processor 53 terminates the processes in the present flowchart, and returns to the processes shown in FIG. 43.

### 5.4.2 Read Diffractive Optical Element Information

FIG. 45 is a flowchart showing the process of reading information on the diffractive optical element 63 in detail. The processes shown in FIG. 45 correspond to the subroutine labeled with S300d in FIG. 43.

In S301, the laser processing processor 53 reads the transmittance T_{DOE} of the diffractive optical element 63. This point is the same as that in Comparative Example.

In S302d, the laser processing processor 53 reads the following information calculated in FIG. 42:
Sum Isum of optical intensities of first and second diffracted luminous fluxes
Optical intensity I_{OK}min of first minimum diffracted luminous flux
Optical intensity ratio R_{N/O} of optical intensity I_{NG}max of second maximum diffracted luminous flux to optical intensity I_{OK}min of first minimum diffracted luminous flux
Optical intensity ratio R_{O/O} of optical intensity I_{OK}max of first maximum diffracted luminous flux to optical intensity I_{OK}min of first minimum diffracted luminous flux

The optical intensity ratio R_{O/O} is used in S403d and S412d described with reference to FIG. 46.

After S302d, the laser processing processor 53 terminates the processes in the present flowchart, and returns to the processes shown in FIG. 43.

### 5.4.3 Determine Target Fluence

FIG. 46 is a flowchart showing the process of determining the target fluence F_{OK}mint of the first minimum diffracted luminous flux in detail. The processes shown in FIG. 46 correspond to the subroutine labeled with S400d in FIG. 43.

In S401b, the laser processing processor 53 calculates the fluence F_{OK}minth of the first minimum diffracted luminous flux, which is provided when the fluence F_{NG}max of the second maximum diffracted luminous flux becomes the processing threshold Fth. This point is the same as that in the second embodiment described with reference to FIG. 30.

In S403d, the laser processing processor 53 calculates the fluence F_{OK}maxth of the first maximum diffracted luminous flux, which is provided when the fluence F_{NG}max of the second maximum diffracted luminous flux becomes the processing threshold Fth using the following expression:

F_{OK}maxth=F_{OK}minth/R_{O/O}

=(Fth/R_{N/O})·R_{O/O}

In S405d, the laser processing processor 53 compares the fluence F_{OK}maxth of the first maximum diffracted luminous flux, which is provided when the fluence F_{NG}max of the second maximum diffracted luminous flux becomes the processing threshold Fth, with the fluence upper limit Fcr. When the fluence F_{OK}maxth is smaller than or equal to the fluence upper limit Fcr (F_{OK}maxth≤Fcr), the laser processing processor 53 proceeds to the process in S410b. When the fluence F_{OK}maxth is greater than the fluence upper limit Fcr (F_{OK}maxth>Fcr), the laser processing processor 53 proceeds to the process in S412d.

In S410b, the laser processing processor 53 determines the target fluence F_{OK}mint that satisfies the following expression (see FIG. 40), as in the second embodiment:

Fth<F_{OK}mint≤Fth/R_{N/O}

In S412d, the laser processing processor 53 determines the target fluence F_{OK}mint that satisfies the following expression (see FIG. 41):

Fth<F_{OK}mint≤Fcr/R_{O/O}

The target fluence F_{OK}mint may be set at Fcr/R_{O/O}, which is the upper limit. This can maximize the efficiency of the laser processing while suppressing the processing performed at the non-processing points that require no processing. The target fluence F_{OK}mint may instead be set at the average of Fth and Fcr/R_{O/O}. In this case, even when the pulse energy of the pulse laser light Out unexpectedly varies, a situation in which the processing is performed at the non-processing points or a situation in which sufficient processing is not performed at the processing points that require the processing can be avoided.

After S410b and S412d, the laser processing processor 53 terminates the processes in the present flowchart, and returns to the processes shown in FIG. 43.

### 5.5 Effects

(8) According to the third embodiment, the first diffracted luminous fluxes vary in terms of the fluence F_{OK}m, and the second diffracted luminous fluxes vary in terms of the fluence F_{NG}m. The laser processing processor 53 controls the adjustment mechanism in such a way that the following conditions are satisfied: (a) The fluence F_{OK}min of the first minimum diffracted luminous flux, which is the minimum of the fluences F_{OK}m, out of the first diffracted luminous fluxes is greater than the processing threshold Fth. (b) The fluence F_{NG}max of the second maximum diffracted luminous flux, which is the maximum of the fluences F_{NG}m, out of the second diffracted luminous fluxes is smaller than or equal to the processing threshold Fth. (c) The fluence F_{OK}max of the first maximum diffracted luminous flux, which is the maximum of the fluences F_{OK}m, out of the first diffracted luminous fluxes, is smaller than or equal to the fluence upper limit Fcr.

Under the conditions described above, even when the plural diffracted luminous fluxes vary in terms of fluence, satisfying the condition on the fluence F_{OK}max of the first maximum diffracted luminous flux allows the fluences F_{OK}m of the first luminous fluxes radiated to the multiple processing points to be a value smaller than or equal to the fluence upper limit Fcr. Therefore, not only can necessary processing be performed with unnecessary processing suppressed but also breakage of the workpiece SUB or other problems can be suppressed.

(9) According to the third embodiment, the laser processing processor 53 compares the fluence F_{OK}maxth of the first maximum diffracted luminous flux, which is provided when the fluence F_{NG}max of the second maximum diffracted luminous flux becomes the processing threshold Fth, with the fluence upper limit Fcr.

When the fluence upper limit Fcr is greater than the fluence F_{OK}maxth of the first maximum diffracted luminous flux, which is provided when the fluence F_{NG}max of the second maximum diffracted luminous flux becomes the processing threshold Fth, the laser processing processor 53 controls the adjustment mechanism in such a way that the following conditions are satisfied: (a) The fluence F_{OK}min of the first minimum diffracted luminous flux is greater than the processing threshold Fth. (b) The fluence F_{NG}max of the second maximum diffracted luminous flux is smaller than or equal to the processing threshold Fth.

When the fluence upper limit Fcr is smaller than the fluence F_{OK}maxth of the first maximum diffracted luminous flux, which is provided when the fluence F_{NG}max of the second maximum diffracted luminous flux becomes the processing threshold Fth, the laser processing processor 53 controls the adjustment mechanism in such a way that the following conditions are satisfied: (a) The fluence F_{OK}min of the first minimum diffracted luminous flux is greater than the processing threshold Fth. (c) The fluence F_{OK}max of the first maximum diffracted luminous flux is smaller than or equal to the fluence upper limit Fcr.

The adjustment mechanism can therefore be controlled with one of the conditions (b) and (c) omitted based on the result of the comparison between the fluence F_{OK}maxth of the first maximum diffracted luminous flux and the fluence upper limit Fcr, so that the control of the adjustment mechanism can be simplified.

(10) According to the third embodiment, the laser processing processor 53 controls the adjustment mechanism such as the attenuator 52 by setting the target fluence F_{OK}mint, which is the target value of the fluence F_{OK}min of the first minimum diffracted luminous flux, as follows: (a) The target fluence F_{OK}mint is greater than the processing threshold Fth. (b) The target fluence F_{OK}mint is smaller than or equal to the value Fth/R_{N/O}, which is a result of division of the processing threshold Fth by the optical intensity ratio R_{N/O}, which is a result of division of the optical intensity I_{NG}max of the second maximum diffracted luminous flux by the optical intensity I_{OK}min of the first minimum diffracted luminous flux. (c) The target fluence F_{OK}mint is smaller than or equal to the value Fcr/R_{O/O}, which is a result of division of the fluence upper limit Fcr by the optical intensity ratio R_{O/O}, which is a result of division of the optical intensity I_{OK}max of the first maximum diffracted luminous flux by the optical intensity I_{OK}min of the first minimum diffracted luminous flux.

Therefore, even when the multiple first diffracted luminous fluxes vary in terms of fluence, the optical intensity ratio R_{O/O} can be used, when the target fluence F_{OK}mint of the first minimum diffracted luminous flux is set, to cause the fluences F_{OK}m of the first luminous fluxes radiated to the multiple processing points to fall within a desired range, so that breakage of the workpiece SUB or other problems can be suppressed.

(11) According to the third embodiment, the laser processing processor 53 compares the fluence F_{OK}maxth of the first maximum diffracted luminous flux, which is provided when the fluence F_{NG}max of the second maximum diffracted luminous flux becomes the processing threshold Fth, with the fluence upper limit Fcr.

When the fluence upper limit Fcr is greater than the fluence F_{OK}maxth of the first maximum diffracted luminous flux, which is provided when the fluence F_{NG}max of the second maximum diffracted luminous flux becomes the processing threshold Fth, the laser processing processor 53 controls the adjustment mechanism such as the attenuator 52 by setting the target fluence F_{OK}mint, which is the target value of the fluence F_{OK}min of the first minimum diffracted luminous flux, as follows: (a) The target fluence F_{OK}mint is greater than the processing threshold Fth. (b) The target fluence F_{OK}mint is smaller than or equal to the value Fth/R_{N/O}, which is a result of division of the processing threshold Fth by the optical intensity ratio R_{N/O}.

When the fluence upper limit Fcr is smaller than the fluence F_{OK}maxth of the first maximum diffracted luminous flux, which is provided when the fluence F_{NG}max of the second maximum diffracted luminous flux becomes the processing threshold Fth, the laser processing processor 53 controls the adjustment mechanism such as the attenuator 52 by setting the target fluence F_{OK}mint as follows: (a) The target fluence F_{OK}mint is greater than the processing threshold Fth. (c) The target fluence F_{OK}mint is smaller than or equal to the value Fcr/R_{O/O}, which is a result of division of the fluence upper limit Fcr by the optical intensity ratio R_{O/O}.

The target fluence F_{OK}mint can therefore be set with one of the conditions (b) and (c) omitted based on the result of the comparison between the fluence F_{OK}maxth of the first maximum diffracted luminous flux and the fluence upper limit Fcr, so that the control of the adjustment mechanism can be simplified.

The third embodiment is otherwise the same as the second embodiment.

6. Laser Processing System in Consideration of Fluence Upper Limit and Variation of Pulse Energy of Pulse Laser Light Output from Laser Apparatus

### 6.1 Concept

### 6.1.1 Fluences of First and Second Diffracted Luminous Fluxes

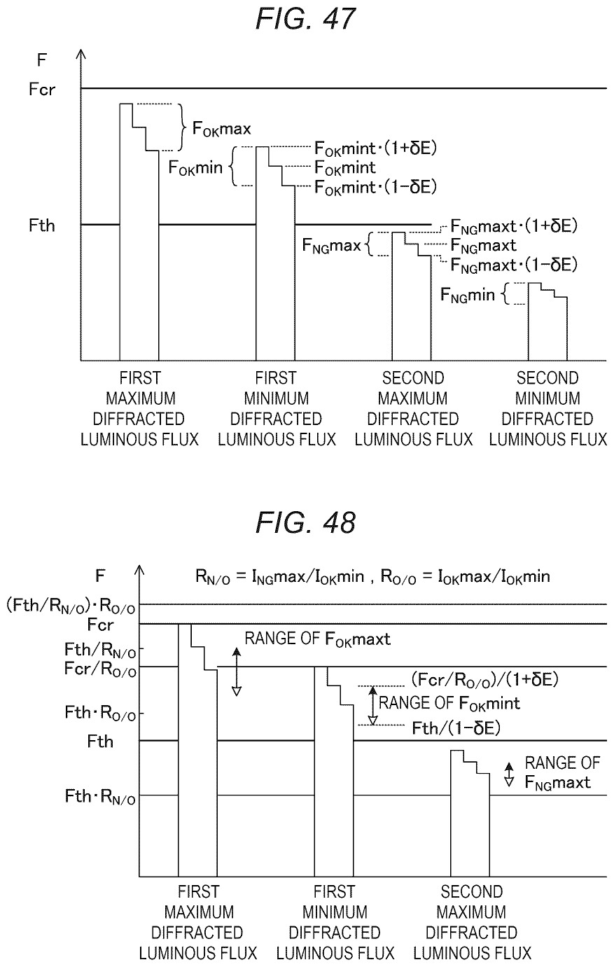

FIG. 47 is a bar graph showing an example of the result of control in a variation of the third embodiment. In the variation of the third embodiment, the variation δE of the pulse energy of the pulse laser light Out output from the laser apparatus 1 is taken into account.

In FIG. 47, the horizontal axis shows the first maximum diffracted luminous flux, the first minimum diffracted luminous flux, the second maximum diffracted luminous flux, and the second minimum diffracted luminous flux, and the vertical axis represents the fluence F of each of the diffracted luminous fluxes at the surface of the workpiece SUB. The fluence F of each of the diffracted luminous fluxes varies based on the pulse energy variation δE as described below.

The range over which the fluence F_{OK}min of the first minimum diffracted luminous flux varies based on the pulse energy variation δE is called a first variation range. The first variation range can be expressed by the following expression using the target fluence F_{OK}mint of the first minimum diffracted luminous flux:

F_{OK}mint·(1−δE)≤F_{OK}min≤F_{OK}mint·(1+δE)

The range over which the fluence F_{NG}max of the second maximum diffracted luminous flux varies based on the pulse energy variation δE is called a second variation range. The second variation range can be expressed by the following expression using a target fluence F_{NG}maxt of the second maximum diffracted luminous flux:

F_{NG}maxt·(1−δE)≤F_{NG}max≤F_{NG}maxt·(1+δE)

The target fluence F_{NG}maxt of the second maximum diffracted luminous flux is obtained by multiplying the target fluence F_{OK}mint of the first minimum diffracted luminous flux by the optical intensity ratio R_{N/O}.

The range over which the fluence F_{OK}max of the first maximum diffracted luminous flux varies based on the pulse energy variation δE is called a third variation range. The third variation range can be expressed by the following expression using the target fluence F_{OK}maxt of the first maximum diffracted luminous flux:

F_{OK}maxt·(1−δE)≤F_{OK}max≤F_{OK}maxt·(1+δE)

The target fluence F_{OK}maxt of the first maximum diffracted luminous flux is obtained by multiplying the target fluence F_{OK}mint of the first minimum diffracted luminous flux by the optical intensity ratio R_{O/O}.

The fluence F_{NG}min of the second minimum diffracted luminous flux similarly varies based on the pulse energy variation δE.

As in the variation of the second embodiment, the laser processing processor 53 controls the adjustment mechanism such as the attenuator 52 in such a way that the minimum value F_{OK}mint·(1−δE) in the first variation range of the fluence F_{OK}min of the first minimum diffracted luminous flux is greater than the processing threshold Fth and the maximum value F_{NG}maxt·(1+δE) in the second variation range of the fluence F_{NG}max of the second maximum diffracted luminous flux is smaller than or equal to the processing threshold Fth. Furthermore, in the variation of the third embodiment, the laser processing processor 53 controls the adjustment mechanism such as the attenuator 52 in such a way that the maximum value F_{OK}maxt (1+δE) in the third variation range of the fluence F_{OK}max of the first maximum diffracted luminous flux is smaller than or equal to the fluence upper limit Fcr.

### 6.1.2 Set Target Fluence F_{OK}mint

FIG. 48 is a bar graph showing an example of the target fluence F_{OK}mint of the first minimum diffracted luminous flux that is set in the variation of the third embodiment. In FIG. 48, the horizontal axis shows the first maximum diffracted luminous flux, the first minimum diffracted luminous flux, and the second maximum diffracted luminous flux, and the vertical axis represents the fluence F of each of the diffracted luminous fluxes at the surface of the workpiece SUB.

### 6.1.2.1 Lower Limit of Target Fluence F_{OK}mint

The target fluence F_{OK}mint is set at a value that causes the minimum value F_{OK}mint·(1−δE) in the first variation range of the fluence F_{OK}min of the first minimum diffracted luminous flux to be a value greater than the processing threshold Fth, as in the variation of the second embodiment. The following relationship is therefore derived:

Fth/(1−δE)<F_{OK}mint

The left-hand side of the above expression, Fth/(1−δE), corresponds to a value as a result of addition of Fth·δE/(1−δE) to the processing threshold Fth. Fth·δE/(1−δE) corresponds to the first variation range in the present disclosure.

### 6.1.2.2 Upper Limit (1) of Target Fluence F_{OK}mint

The target fluence F_{OK}mint is set at a value that causes the maximum value F_{NG}maxt·(1+δE) in the second variation range of the fluence F_{NG}max of the second maximum diffracted luminous flux to be a value smaller than or equal to the processing threshold Fth, as in the variation of the second embodiment. The following relationship is therefore derived:

F_{OK}mint≤(Fth/R_{N/O})/(1+δE)

The right-hand side of the above expression, (Fth/R_{N/O})/(1+δE), corresponds to a value as a result of subtraction of (Fth/R_{N/O})·δE/(1+δE) from the value Fth/R_{N/O} as a result of division of the processing threshold Fth by the optical intensity ratio R_{N/O}. (Fth/R_{N/O})·δE/(1+δE) corresponds to the second variation range in the present disclosure.

### 6.1.2.3 Upper Limit (2) of Target Fluence F_{OK}mint

The target fluence F_{OK}mint is set at a value that causes the maximum value F_{OK}maxt (1+δE) in the third variation range of the fluence F_{OK}max of the first maximum diffracted luminous flux to be a value smaller than or equal to the fluence upper limit Fcr. The following relationship is therefore given:

F_{OK}maxt·(1+δE)≤Fcr

F_{OK}maxt is a value obtained by multiplying the target fluence F_{OK}mint of the first minimum diffracted luminous flux by the optical intensity ratio R_{O/O}. The following relationship is therefore derived from the above inequality.

F_{OK}mint≤(Fcr/R_{O/O})/(1+δE)

The right-hand side of the above expression, (Fcr/R_{O/O})/(1+δE), corresponds to a value as a result of subtraction of (Fcr/R_{O/O}) 6E/(1+δE) from the value Fcr/R_{O/O} as a result of division of the fluence upper limit Fcr by the optical intensity ratio R_{O/O}, as expressed by the following expression:

(Fcr/R_{O/O})/(1+δE)=Fcr/R_{O/O}−(Fcr/R_{O/O})·δE/(1+δE)

(Fcr/R_{O/O})·δE/(1+δE) corresponds to the third variation range in the present disclosure.

Setting the upper limit of the target fluence F_{OK}mint of the first minimum diffracted luminous flux as described above causes the maximum value F_{OK}maxt (1+δE) in the third variation range of the fluence F_{OK}max of the first maximum diffracted luminous flux to be a value smaller than or equal to the fluence upper limit Fcr. The fluences of the first diffracted luminous fluxes including the fluence F_{OK}min of the first minimum diffracted luminous flux, which are all smaller than or equal to the maximum value F_{OK}maxt (1+δE) in the third variation range of the fluence F_{OK}max of the first maximum diffracted luminous flux, are also smaller than or equal to the fluence upper limit Fcr.

### 6.1.2.4 Range of Target Fluence F_{OK}mint

In the variation of the third embodiment, the target fluence F_{OK}mint has two upper limits, as described above. That is, the target fluence F_{OK}mint is set at a value smaller than or equal to the value (Fth/R_{N/O})/(1+δE) and smaller than or equal to the value (Fcr/R_{O/O})/(1+δE).

When the value (Fcr/R_{O/O})/(1+δE) is greater than the value (Fth/R_{N/O})/(1+δE), that is, when the fluence upper limit Fcr is greater than the value (Fth/R_{N/O})·R_{O/O}, making the target fluence F_{OK}mint smaller than or equal to the value (Fth/R_{N/O})/(1+δE) eliminates the need for consideration of the value (Fcr/R_{O/O})/(1+δE).

In this case, setting the target fluence F_{OK}mint at a value that falls within the range expressed by the following expression causes the fluence F_{OK}min of the first minimum diffracted luminous flux to be a value greater than the processing threshold Fth, the fluence F_{OK}max of the first maximum diffracted luminous flux to be a value smaller than or equal to the fluence upper limit Fcr, and the fluence F_{NG}max of the second maximum diffracted luminous flux to be a value smaller than or equal to the processing threshold Fth, as in the variation of the second embodiment:

Fth/(1−δE)<F_{OK} mint≤(Fth/R_{N/O})/(1+δE)

In other words, when the fluence upper limit Fcr is greater than the value (Fth/R_{N/O})·R_{O/O}, the adjustment mechanism may be so controlled that the minimum value F_{OK}mint·(1−δE) in the first variation range of the fluence F_{OK}min of the first minimum diffracted luminous flux is greater than the processing threshold Fth and the maximum value F_{NG}maxt·(1+δE) in the second variation range of the fluence F_{NG}max of the second maximum diffracted luminous flux is smaller than or equal to the processing threshold Fth.

When the value (Fcr/R_{O/O})/(1+δE) is smaller than the value (Fth/R_{N/O})/(1+δE), that is, when the fluence upper limit Fcr is smaller than the value (Fth/R_{N/O})·R_{O/O}, making the target fluence F_{OK}mint smaller than or equal to the value (Fcr/R_{O/O})/(1+δE) eliminates the need for consideration of the value (Fth/R_{N/O})/(1+δE) (see FIG. 48).

In this case, setting the target fluence F_{OK}mint at a value that falls within the range shown below causes the fluence F_{OK}min of the first minimum diffracted luminous flux to be a value greater than the processing threshold Fth, the fluence F_{OK}max of the first maximum diffracted luminous flux to be a value smaller than or equal to the fluence upper limit Fcr, and the fluence F_{NG}max of the second maximum diffracted luminous flux to be a value smaller than or equal to the processing threshold Fth.

Fth/(1−δE)<F_{OK}mint≤(Fcr/R_{O/O})/(1+δE)

In other words, when the fluence upper limit Fcr is smaller than the value (Fth/R_{N/O})·R_{O/O}, the adjustment mechanism may be so controlled that the minimum value F_{OK}mint·(1−δE) in the first variation range of the fluence F_{OK}min of the first minimum diffracted luminous flux is greater than the processing threshold Fth and the maximum value F_{OK}maxt (1+δE) in the third variation range of the fluence F_{OK}max of the first maximum diffracted luminous flux is smaller than or equal to the fluence upper limit Fcr.

### 6.2 Configuration of Laser Processing System

The configuration of the laser processing system according to the variation of the third embodiment is the same as the configuration in Comparative Example described with reference to FIG. 1.

### 6.3 Processes Carried Out by Laser Processing Processor 53

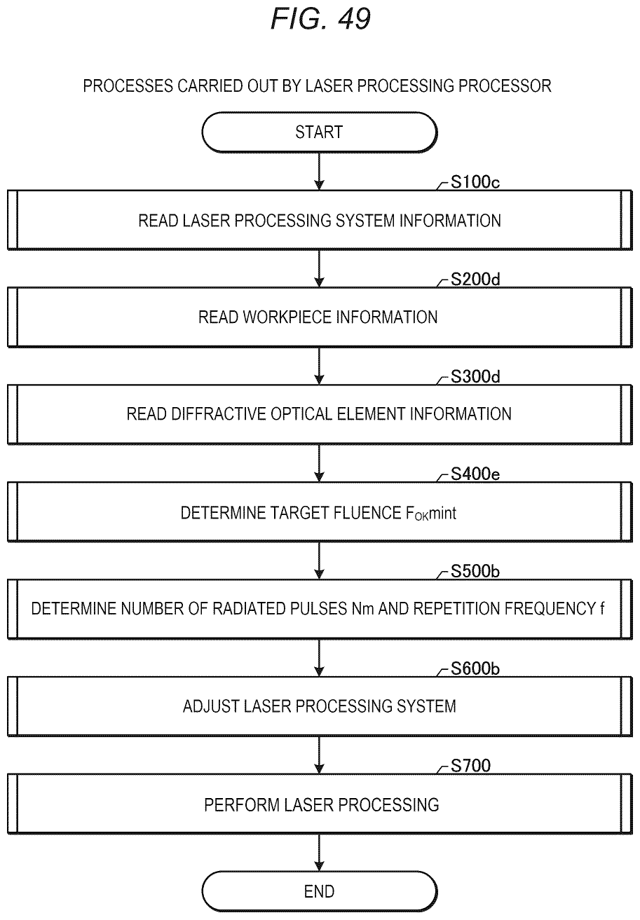

FIG. 49 is a flowchart showing laser processing processes in the variation of the third embodiment. Out of the laser processing processes in the variation of the third embodiment, the processes in S100c and S400e differ from the corresponding processes in the third embodiment.

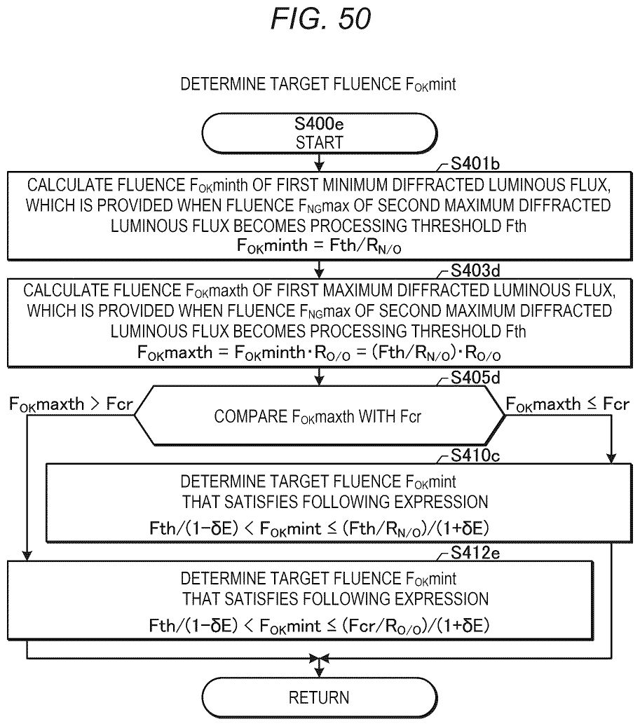

The process in S100c is the same as that in the variation of the second embodiment described with reference to FIG. 36. The process in S400e will be described below in detail with reference to FIG. 50.

FIG. 50 is a flowchart showing the process of determining the target fluence F_{OK}mint of the first minimum diffracted luminous flux in detail. The processes shown in FIG. 50 correspond to the subroutine labeled with S400e in FIG. 49.

The processes in steps from S401b to S405d are the same as those in the third embodiment. In S405d, when the fluence F_{OK}maxth is smaller than or equal to the fluence upper limit Fcr (F_{OK}maxth≤Fcr), the laser processing processor 53 proceeds to the process in S410c. When the fluence F_{OK}maxth is greater than the fluence upper limit Fcr (F_{OK}maxth>Fcr), the laser processing processor 53 proceeds to the process in S412e.

In S410c, the laser processing processor 53 determines the target fluence F_{OK}mint that satisfies the following expression, as in the variation of the second embodiment:

Fth/(1−δE)<F_{OK}mint≤(Fth/R_{N/O})/(1+δE)

In S412e, the laser processing processor 53 determines the target fluence F_{OK}mint that satisfies the following expression (see FIG. 48):

Fth/(1−δE)<F_{OK}mint≤(Fcr/R_{O/O})/(1+δE)

The target fluence F_{OK}mint may be set at (Fcr/R_{O/O})/(1+δE), which is the upper limit. This can maximize the efficiency of the laser processing while suppressing the processing performed at the non-processing points that require no processing. The target fluence F_{OK}mint may instead be set at the average of Fth/(1−δE) and (Fcr/R_{O/O})/(1+δE). In this case, even when the pulse energy of the pulse laser light Out unexpectedly varies, a situation in which the processing is performed at the non-processing points or a situation in which sufficient processing is not performed at the processing points that require the processing can be avoided.

After S410c and S412e, the laser processing processor 53 terminates the processes in the present flowchart, and returns to the processes shown in FIG. 49.

### 6.4 Effects

(12) According to the variation of the third embodiment, the first diffracted luminous fluxes vary in terms of the fluence F_{OK}m, and the second diffracted luminous fluxes vary in terms of the fluence F_{NG}m. The laser processing processor 53 controls the adjustment mechanism in such a way that the following conditions are satisfied: (a) The minimum value F_{OK}mint·(1−δE) in the first variation range of the fluence F_{OK}min of the first minimum diffracted luminous flux having the minimum of the fluences F_{OK}m out of the first diffracted luminous fluxes, the first variation range derived based on the variation δE of the pulse energy of the pulse laser light Out incident on the diffractive optical element 63, is greater than the processing threshold Fth. (b) The maximum value F_{NG}maxt·(1+δE) in the second variation range of the fluence F_{NG}max of the second maximum diffracted luminous flux having the maximum of the fluences F_{NG}m out of the second diffracted luminous fluxes, the second variation range derived based on the pulse energy variation δE, is smaller than or equal to the processing threshold Fth. (c) The maximum value F_{OK}maxt (1+δE) in the third variation range of the fluence F_{OK}max of the first maximum diffracted luminous flux having the maximum of the fluences F_{OK}m out of the first diffracted luminous fluxes, the third variation range derived based on the pulse energy variation δE, is smaller than or equal to the fluence upper limit Fcr.

With the conditions described above satisfied, the entire variation range of the fluences F_{OK}m of the first diffracted luminous fluxes radiated to the multiple processing points can be smaller than or equal to the fluence upper limit Fcr not only when the multiple diffracted luminous fluxes vary in terms of fluence but also when the pulse laser light Out contains the pulse energy variation δE. Therefore, not only can necessary processing be performed with unnecessary processing suppressed but also breakage of the workpiece SUB or other problems can be suppressed.

(13) According to the variation of the third embodiment, the laser processing processor 53 compares the fluence F_{OK}maxth of the first maximum diffracted luminous flux provided when the fluence F_{NG}max of the second maximum diffracted luminous flux becomes the processing threshold Fth with the fluence upper limit Fcr.

When the fluence upper limit Fcr is greater than the fluence F_{OK}maxth of the first maximum diffracted luminous flux, which is provided when the fluence F_{NG}max of the second maximum diffracted luminous flux becomes the processing threshold Fth, the laser processing processor 53 controls the adjustment mechanism in such a way that the following conditions are satisfied: (a) The minimum value F_{OK}mint·(1−δE) in the first variation range of the fluence F_{OK}min of the first minimum diffracted luminous flux, the first variation range derived based on the pulse energy variation δE, is greater than the processing threshold Fth. (b) The maximum value F_{NG}maxt·(1+δE) in the second variation range of the fluence F_{NG}max of the second maximum diffracted luminous flux, the second variation range derived based on the pulse energy variation δE, is smaller than or equal to the processing threshold Fth.

When the fluence upper limit Fcr is smaller than the fluence F_{OK}maxth of the first maximum diffracted luminous flux, which is provided when the fluence F_{NG}max of the second maximum diffracted luminous flux becomes the processing threshold Fth, the laser processing processor 53 controls the adjustment mechanism in such a way that the following conditions are satisfied: (a) The minimum value F_{OK}mint·(1−δE) in the first variation range of the fluence F_{OK}min of the first minimum diffracted luminous flux is greater than the processing threshold Fth. (c) The maximum value F_{OK}maxt (1+δE) in the third variation range of the fluence F_{OK}max of the first maximum diffracted luminous flux, the third variation range derived based on the pulse energy variation δE, is smaller than or equal to the fluence upper limit Fcr.

The adjustment mechanism can therefore be controlled with one of the conditions (b) and (c) omitted based on the result of the comparison between the fluence F_{OK}maxth of the first maximum diffracted luminous flux and the fluence upper limit Fcr, so that the control of the adjustment mechanism can be simplified.

(14) According to the variation of the third embodiment, the laser processing processor 53 controls the adjustment mechanism such as the attenuator 52 by setting the target fluence F_{OK}mint, which is the target value of the fluence F_{OK}min of the first minimum diffracted luminous flux, as follows: (a) The target fluence F_{OK}mint is greater than the value Fth/(1−δE) as a result of addition of the first variation range Fth·δE/(1−δE), which indicates the pulse energy variation δE, to the processing threshold Fth. (b) The target fluence F_{OK}mint is smaller than or equal to the value (Fth/R_{N/O})/(1+δE), which is a result of subtraction of the second variation range (Fth/R_{N/O})·δE/(1+δE) indicating the pulse energy variation δE from the value Fth/R_{N/O}, which is a result of division of the processing threshold Fth by the optical intensity ratio R_{N/O}, which is a result of division of the optical intensity I_{NG}max of the second maximum diffracted luminous flux by the optical intensity I_{OK}min of the first minimum diffracted luminous flux. (c) The target fluence F_{OK}mint is smaller than or equal to the value (Fcr/R_{O/O})/(1+δE), which is a result of subtraction of the third variation range (Fcr/R_{O/O}) 6E/(1+δE) indicating the pulse energy variation δE from the value Fcr/R_{O/O}, which is a result of division of the fluence upper limit Fcr by the optical intensity ratio R_{O/O}, which is a result of division of the optical intensity I_{OK}max of the first maximum diffracted luminous flux by the optical intensity I_{OK}min of the first minimum diffracted luminous flux.

Therefore, even when not only the multiple first diffracted luminous fluxes vary in terms of fluence but also the pulse laser light Out contains the pulse energy variation δE, the optical intensity ratio R_{O/O} can be used, when the target fluence F_{OK}mint of the first minimum diffracted luminous flux is set, to cause the fluences F_{OK}m of the first luminous fluxes radiated to the multiple processing points to fall within a desired range.

(15) According to the variation of the third embodiment, the laser processing processor 53 compares the fluence F_{OK}maxth of the first maximum diffracted luminous flux, which is provided when the fluence F_{NG}max of the second maximum diffracted luminous flux becomes the processing threshold Fth, with the fluence upper limit Fcr.

When the fluence upper limit Fcr is greater than the fluence F_{OK}maxth of the first maximum diffracted luminous flux, which is provided when the fluence F_{NG}max of the second maximum diffracted luminous flux becomes the processing threshold Fth, the laser processing processor 53 controls the adjustment mechanism such as the attenuator 52 by setting the target fluence F_{OK}mint, which is the target value of the fluence F_{OK}min of the first minimum diffracted luminous flux, as follows: (a) The target fluence F_{OK}mint is greater than the value Fth/(1−δE) as a result of addition of the first variation range Fth SE/(1−δE), which indicates the pulse energy variation δE, to the processing threshold Fth. (b) The target fluence F_{OK}mint is smaller than or equal to the value (Fth/R_{N/O})/(1+δE), which is a result of subtraction of the second variation range (Fth/R_{N/O})·δE/(1+δE) indicating the pulse energy variation δE from the value Fth/R_{N/O}, which is a result of division of the processing threshold Fth by the optical intensity ratio R_{N/O}.

When the fluence upper limit Fcr is smaller than the fluence F_{OK}maxth of the first maximum diffracted luminous flux, which is provided when the fluence F_{NG}max of the second maximum diffracted luminous flux becomes the processing threshold Fth, the laser processing processor 53 controls the adjustment mechanism such as the attenuator 52 by setting the target fluence F_{OK}mint as follows: (a) The target fluence F_{OK}mint is greater than the value Fth/(1−δE) as a result of addition of the first variation range Fth 6E/(1−δE) to the processing threshold Fth. (c) The target fluence F_{OK}mint is smaller than or equal to the value (Fcr/R_{O/O})/(1+δE) as a result of subtraction of the third variation range (Fcr/R_{O/O})·δE/(1+δE) indicating the pulse energy variation δE from the value Fcr/R_{O/O} as a result of division of the fluence upper limit Fcr by the optical intensity ratio R_{O/O}.

The target fluence F_{OK}mint can therefore be set with one of the conditions (b) and (c) omitted based on the result of the comparison between the fluence F_{OK}maxth of the first maximum diffracted luminous flux and the fluence upper limit Fcr, so that the control of the adjustment mechanism can be simplified.

The variation of the third embodiment is otherwise the same as the third embodiment.

### 7. Others

### 7.1 Configuration of Electronic Device

FIG. 51 diagrammatically shows the configuration of an electronic device. The electronic device shown in FIG. 51 includes the integrated circuit chip IC, the interposer IP, and the circuit substrate CS.

The integrated circuit chip IC is, for example, a chip in which an integrated circuit that is not shown is formed in a silicon substrate. The integrated circuit chip IC is provided with multiple bumps ICB electrically connected to the integrated circuit.

The interposer IP includes an insulating substrate having multiple through holes that are not shown but are formed therein, and an electrical conductor that is not shown but electrically connects the front and rear sides of the substrate to each other is provided in each of the through holes. Multiple lands that are not shown but are connected to the bumps ICB are formed at one surface of the interposer IP, and the lands are each electrically connected to one of the electrical conductors in the through holes. Multiple bumps IPB are provided at the other surface of the interposer IP, and the bumps IPB are each electrically connected to one of the electrical conductors in the through holes.

Multiple lands that are not shown but are connected to the bumps IPB are formed at one surface of the circuit substrate CS. The circuit substrate CS includes multiple terminals to be electrically connected to the lands.

### 7.2 Method for Manufacturing Electronic Device

FIG. 52 is a flowchart showing a method for manufacturing an electronic device.

In step S1, the interposer substrate, which constitutes the interposer IP, is processed with laser light, and wiring is formed in the interposer substrate. The laser processing performed on the interposer substrate includes forming through holes by irradiating the interposer substrate, which is an example of the workpiece SUB, with the pulse laser light Out. The wiring formation includes forming an electrically conductive film at the inner wall surface of each of the through holes formed in the interposer substrate. The interposer IP is produced through the steps described above.

In step S2, the interposer IP and the integrated circuit chip IC are coupled to each other. Step S2 includes, for example, placing the bumps ICB of the integrated circuit chip IC on the lands of the interposer IP, and electrically connecting the bumps ICB and the lands to each other.

In step S3, the interposer IP and the circuit substrate CS are coupled to each other. Step S3 includes, for example, placing the bumps IPB of the interposer IP on the lands of the circuit substrate CS, and electrically connecting the bumps IPB and the lands to each other.

### 7.3 Supplements

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, the term “at least one of A, B, and C” should be interpreted to mean any of A, B, C, A+B, A+C, B+C, and A+B+C. Moreover, the term described above should be interpreted to include combinations of any thereof and any other than A, B, and C.

What is claimed is:

1. A laser processing system comprising:
a laser apparatus configured to output pulse laser light;
a diffractive optical element configured to divide the pulse laser light into multiple first diffracted luminous fluxes to be radiated to multiple processing points on a workpiece, and multiple second diffracted luminous fluxes to be radiated to multiple non-processing points on the workpiece;
a focusing optical system configured to focus each of the first and second diffracted luminous fluxes at the workpiece;
an adjustment mechanism configured to adjust pulse energy of the pulse laser light incident on the diffractive optical element; and
a processor configured to control the adjustment mechanism based on parameters including a processing threshold Fth of a fluence for processing the workpiece in such a way that
a fluence F_{OK}m of the first diffracted luminous fluxes at a surface of the workpiece is greater than the processing threshold Fth, and
a fluence F_{NG}m of the second diffracted luminous fluxes at the surface of the workpiece is smaller than or equal to the processing threshold Fth.

2. The laser processing system according to claim 1, wherein
the processor is configured to control the adjustment mechanism by setting a target fluence F_{OK}mt, which is a target value of the fluence F_{OK}m of the first diffracted luminous fluxes, in such a way that the target fluence F_{OK}mt
is greater than the processing threshold Fth, and
is smaller than or equal to a value Fth/R, which is a result of division of the processing threshold Fth by an optical intensity ratio R, which is a result of division of an optical intensity I_{NG} of the second diffracted luminous fluxes at the surface of the workpiece by an optical intensity I_{OK} of the first diffracted luminous fluxes at the surface of the workpiece.

3. The laser processing system according to claim 1, wherein
the multiple first diffracted luminous fluxes vary in terms of the fluence F_{OK}m, and the multiple second diffracted luminous fluxes vary in terms of the fluence F_{NG}m, and
the processor is configured to control the adjustment mechanism in such a way that
a fluence F_{OK}min of a first minimum diffracted luminous flux having a minimum of the fluences F_{OK}m out of the multiple first diffracted luminous fluxes is greater than the processing threshold Fth, and
a fluence F_{NG}max of a second maximum diffracted luminous flux having a maximum of the fluences F_{NG}m out of the multiple second diffracted luminous fluxes is smaller than or equal to the processing threshold Fth.

4. The laser processing system according to claim 1, wherein
the multiple first diffracted luminous fluxes vary in terms of the fluence F_{OK}m, and the multiple second diffracted luminous fluxes vary in terms of the fluence F_{NG}m, and
the processor is configured to control the adjustment mechanism by setting a target fluence F_{OK}mint, which is a target value of a fluence F_{OK}min of a first minimum diffracted luminous flux having a minimum of the fluences F_{OK}m out of the multiple first diffracted luminous fluxes, in such a way that the target fluence F_{OK}mint
is greater than the processing threshold Fth, and
is smaller than or equal to a value Fth/R_{N/O}, which is a result of division of the processing threshold Fth by an optical intensity ratio R_{N/O}, which is a result of division of an optical intensity I_{NG}max of a second maximum diffracted luminous flux having a maximum of the fluences F_{NG}m out of the multiple second diffracted luminous fluxes by an optical intensity I_{OK}min of the first minimum diffracted luminous flux.

5. The laser processing system according to claim 4, wherein
the processor is configured to control the adjustment mechanism by calculating a parameter for adjusting the pulse energy of the pulse laser light incident on the diffractive optical element based on a ratio of a sum Isum of optical intensities of the first and second diffracted luminous fluxes to the optical intensity I_{OK}min of the first minimum diffracted luminous flux, and the target fluence F_{OK}mint.

6. The laser processing system according to claim 1, wherein
the multiple first diffracted luminous fluxes vary in terms of the fluence F_{OK}m, and the multiple second diffracted luminous fluxes vary in terms of the fluence F_{NG}m, and
the processor is configured to control the adjustment mechanism in such a way that
a minimum in a first variation range of a fluence F_{OK}min of a first minimum diffracted luminous flux having a minimum of the fluences F_{OK}m out of the multiple first diffracted luminous fluxes, the first variation range derived based on a pulse energy variation SE of the pulse energy of the pulse laser light incident on the diffractive optical element, is greater than the processing threshold Fth, and
a maximum in a second variation range of a fluence F_{NG}max of a second maximum diffracted luminous flux having a maximum of the fluences F_{NG}m out of the multiple second diffracted luminous fluxes, the second variation range derived based on the pulse energy variation SE, is smaller than or equal to the processing threshold Fth.

7. The laser processing system according to claim 1, wherein
the multiple first diffracted luminous fluxes vary in terms of the fluence F_{OK}m, and the multiple second diffracted luminous fluxes vary in terms of the fluence F_{NG}m, and
the processor is configured to control the adjustment mechanism by setting a target fluence F_{OK}mint, which is a target value of a fluence F_{OK}min of a first minimum diffracted luminous flux having a minimum of the fluences F_{OK}m out of the multiple first diffracted luminous fluxes, in such a way that the target fluence F_{OK}mint
is greater than a value as a result of addition of a first variation range indicating a pulse energy variation δE of the pulse energy of the pulse laser light incident on the diffractive optical element to the processing threshold Fth, and
is smaller than or equal to a value as a result of subtraction of a second variation range indicating the pulse energy variation SE from a value Fth/R_{N/O}, which is a result of division of the processing threshold Fth by an optical intensity ratio R_{N/O}, which is a result of division of an optical intensity I_{NG}max of a second maximum diffracted luminous flux having a maximum of the fluences F_{NG}m out of the multiple second diffracted luminous fluxes by an optical intensity I_{OK}min of the first minimum diffracted luminous flux.

8. The laser processing system according to claim 1, wherein
the multiple first diffracted luminous fluxes vary in terms of the fluence F_{OK}m, and the multiple second diffracted luminous fluxes vary in terms of the fluence F_{NG}m, and
the processor is configured to control the adjustment mechanism in such a way that
a fluence F_{OK}min of a first minimum diffracted luminous flux having a minimum of the fluences F_{OK}m out of the multiple first diffracted luminous fluxes is greater than the processing threshold Fth,
a fluence F_{NG}max of a second maximum diffracted luminous flux having a maximum of the fluences F_{NG}m out of the multiple second diffracted luminous fluxes is smaller than or equal to the processing threshold Fth, and
a fluence F_{OK}max of a first maximum diffracted luminous flux having a maximum of the fluences F_{OK}m out of the multiple first diffracted luminous fluxes is smaller than or equal to a fluence upper limit Fcr.

9. The laser processing system according to claim 1, wherein
the multiple first diffracted luminous fluxes vary in terms of the fluence F_{OK}m, and the multiple second diffracted luminous fluxes vary in terms of the fluence F_{NG}m, and
the processor is configured to
compare a fluence upper limit Fcr with a fluence F_{OK}maxth of a first maximum diffracted luminous flux having a maximum of the fluences F_{OK}m out of the multiple first diffracted luminous fluxes, which is provided when a fluence F_{NG}max of a second maximum diffracted luminous flux having a maximum of the fluences F_{NG}m out of the multiple second diffracted luminous fluxes becomes the processing threshold Fth,
control the adjustment mechanism when the fluence upper limit Fcr is greater than the fluence F_{OK}maxth of the first maximum diffracted luminous flux, which is provided when the fluence F_{NG}max of the second maximum diffracted luminous flux becomes the processing threshold Fth, in such a way that
a fluence F_{OK}min of a first minimum diffracted luminous flux having a minimum of the fluences F_{OK}m out of the multiple first diffracted luminous fluxes is greater than the processing threshold Fth, and
the fluence F_{NG}max of the second maximum diffracted luminous flux is smaller than or equal to the processing threshold Fth, and
control the adjustment mechanism when the fluence upper limit Fcr is smaller than the fluence F_{OK}maxth of the first maximum diffracted luminous flux, which is provided when the fluence F_{NG}max of the second maximum diffracted luminous flux becomes the processing threshold Fth, in such a way that
the fluence F_{OK}min of the first minimum diffracted luminous flux is greater than the processing threshold Fth, and
the fluence F_{OK}max of the first maximum diffracted luminous flux is smaller than or equal to the fluence upper limit Fcr.

10. The laser processing system according to claim 1, wherein
the multiple first diffracted luminous fluxes vary in terms of the fluence F_{OK}m, and the multiple second diffracted luminous fluxes vary in terms of the fluence F_{NG}m, and
the processor is configured to control the adjustment mechanism by setting a target fluence F_{OK}mint, which is a target value of a fluence F_{OK}min of a first minimum diffracted luminous flux having a minimum of the fluences F_{OK}m out of the multiple first diffracted luminous fluxes, in such a way that the target fluence F_{OK}mint
is greater than the processing threshold Fth,
is smaller than or equal to a value Fth/R_{N/O}, which is a result of division of the processing threshold Fth by an optical intensity ratio R_{N/O}, which is a result of division of an optical intensity I_{NG}max of a second maximum diffracted luminous flux having a maximum of the fluences F_{NG}m out of the multiple second diffracted luminous fluxes by an optical intensity I_{OK}min of the first minimum diffracted luminous flux, and
is smaller than or equal to a value Fcr/R_{O/O}, which is a result of division of a fluence upper limit Fcr by an optical intensity ratio R_{O/O}, which is a result of division of an optical intensity I_{OK}max of a first maximum diffracted luminous flux having a maximum of the fluences F_{OK}m out of the multiple first diffracted luminous fluxes by the optical intensity I_{OK}min of the first minimum diffracted luminous flux.

11. The laser processing system according to claim 1, wherein
the multiple first diffracted luminous fluxes vary in terms of the fluence F_{OK}m, and the multiple second diffracted luminous fluxes vary in terms of the fluence F_{NG}m, and
the processor is configured to
compare a fluence upper limit Fcr with a fluence F_{OK}maxth of a first maximum diffracted luminous flux having a maximum of the fluences F_{OK}m out of the multiple first diffracted luminous fluxes, which is provided when a fluence F_{NG}max of a second maximum diffracted luminous flux having a maximum of the fluences F_{NG}m out of the multiple second diffracted luminous fluxes becomes the processing threshold Fth,
control the adjustment mechanism when the fluence upper limit Fcr is greater than the fluence F_{OK}maxth of the first maximum diffracted luminous flux, which is provided when the fluence F_{NG}max of the second maximum diffracted luminous flux becomes the processing threshold Fth, by setting a target fluence F_{OK}mint, which is a target value of a fluence F_{OK}min of a first minimum diffracted luminous flux having a minimum of the fluences F_{OK}m out of the multiple first diffracted luminous fluxes, in such a way that the target fluence F_{OK}mint
is greater than the processing threshold Fth, and
is smaller than or equal to a value Fth/R_{N/O}, which is a result of division of the processing threshold Fth by an optical intensity ratio R_{N/O}, which is a result of division of an optical intensity I_{NG}max of the second maximum diffracted luminous flux by an optical intensity I_{OK}min of the first minimum diffracted luminous flux, and
control the adjustment mechanism when the fluence upper limit Fcr is smaller than the fluence F_{OK}maxth of the first maximum diffracted luminous flux, which is provided when the fluence F_{NG}max of the second maximum diffracted luminous flux becomes the processing threshold Fth, by setting the target fluence F_{OK}mint in such a way that the target fluence F_{OK}mint
is greater than the processing threshold Fth, and
is smaller than or equal to a value Fcr/R_{O/O}, which is a result of division of the fluence upper limit Fcr by an optical intensity ratio R_{O/O}, which is a result of division of an optical intensity I_{OK}max of the first maximum diffracted luminous flux, by the optical intensity I_{OK}min of the first minimum diffracted luminous flux.

12. The laser processing system according to claim 1, wherein
the multiple first diffracted luminous fluxes vary in terms of the fluence F_{OK}m, and the multiple second diffracted luminous fluxes vary in terms of the fluence F_{NG}m, and
the processor is configured to control the adjustment mechanism in such a way that
a minimum in a first variation range of a fluence F_{OK}min of a first minimum diffracted luminous flux having a minimum of the fluences F_{OK}m out of the multiple first diffracted luminous fluxes, the first variation range derived based on a pulse energy variation δE of pulse energy of the pulse laser light incident on the diffractive optical element, is greater than the processing threshold Fth,
a maximum in a second variation range of a fluence F_{NG}max of a second maximum diffracted luminous flux having a maximum of the fluences F_{NG}m out of the multiple second diffracted luminous fluxes, the second variation range derived based on the pulse energy variation δE, is smaller than or equal to the processing threshold Fth, and
a maximum in a third variation range of a fluence F_{OK}max of a first maximum diffracted luminous flux having a maximum of the fluences F_{OK}m out of the multiple first diffracted luminous fluxes, the third variation range derived based on the pulse energy variation δE, is smaller than or equal to a fluence upper limit Fcr.

13. The laser processing system according to claim 1, wherein
the multiple first diffracted luminous fluxes vary in terms of the fluence F_{OK}m, and the multiple second diffracted luminous fluxes vary in terms of the fluence F_{NG}m, and
the processor is configured to
compare a fluence upper limit Fcr with a fluence F_{OK}maxth of a first maximum diffracted luminous flux, which is provided when a fluence F_{NG}max of a second maximum diffracted luminous flux having a maximum of the fluences F_{NG}m out of the multiple second diffracted luminous fluxes becomes the processing threshold Fth,
control the adjustment mechanism when the fluence upper limit Fcr is greater than the fluence F_{OK}maxth of the first maximum diffracted luminous flux, which is provided when the fluence F_{NG}max of the second maximum diffracted luminous flux becomes the processing threshold Fth, in such a way that
a minimum in a first variation range of a fluence F_{OK}min of a first minimum diffracted luminous flux having a minimum of the fluences F_{OK}m out of the multiple first diffracted luminous fluxes, the first variation range derived based on a pulse energy variation δE of the pulse energy of the pulse laser light incident on the diffractive optical element, is greater than the processing threshold Fth, and
a maximum value in a second variation range of the fluence F_{NG}max of the second maximum diffracted luminous flux, the second variation range derived based on the pulse energy variation δE, is smaller than or equal to the processing threshold Fth, and
control the adjustment mechanism when the fluence upper limit Fcr is smaller than the fluence F_{OK}maxth of the first maximum diffracted luminous flux, which is provided when the fluence F_{NG}max of the second maximum diffracted luminous flux becomes the processing threshold Fth in such a way that
a minimum in the first variation range of the fluence F_{OK}min of the first minimum diffracted luminous flux is greater than the processing threshold Fth, and
a maximum value in a third variation range of a fluence F_{OK}max of the first maximum diffracted luminous flux, the third variation range derived based on the pulse energy variation δE, is smaller than or equal to the fluence upper limit Fcr.

14. The laser processing system according to claim 1, wherein
the multiple first diffracted luminous fluxes vary in terms of the fluence F_{OK}m, and the multiple second diffracted luminous fluxes vary in terms of the fluence F_{NG}m, and
the processor is configured to control the adjustment mechanism by setting a target fluence F_{OK}mint, which is a target value of a fluence F_{OK}min of a first minimum diffracted luminous flux having a minimum of the fluences F_{OK}m out of the multiple first diffracted luminous fluxes, in such a way that the target fluence F_{OK}mint
is greater than a value as a result of addition of a first variation range indicating pulse energy variation δE of the pulse energy of the pulse laser light incident on the diffractive optical element to the processing threshold Fth,
is smaller than or equal to a value as a result of subtraction of a second variation range indicating the pulse energy variation SE from a value Fth/R_{N/O}, which is a result of division of the processing threshold Fth by an optical intensity ratio R_{N/O}, which is a result of division of an optical intensity I_{NG}max of a second maximum diffracted luminous flux having a maximum of the fluences F_{NG}m out of the multiple second diffracted luminous fluxes by an optical intensity I_{OK}min of the first minimum diffracted luminous flux, and
is smaller than or equal to a value as a result of subtraction of a third variation range indicating the pulse energy variation δE from a value Fcr/R_{O/O}, which is a result of division of a fluence upper limit Fcr by an optical intensity ratio R_{O/O}, which is a result of division of an optical intensity I_{OK}max of a first maximum diffracted luminous flux having a maximum of the fluences F_{OK}m out of the multiple first diffracted luminous fluxes by the optical intensity I_{OK}min of the first minimum diffracted luminous flux.

15. The laser processing system according to claim 1, wherein
the multiple first diffracted luminous fluxes vary in terms of the fluence F_{OK}m, and the multiple second diffracted luminous fluxes vary in terms of the fluence F_{NG}m, and
the processor is configured to
compare a fluence upper limit Fcr with a fluence F_{OK}maxth of a first maximum diffracted luminous flux having a maximum of the fluences F_{OK}m out of the multiple first diffracted luminous fluxes, which is provided when a fluence F_{NG}max of a second maximum diffracted luminous flux having a maximum of the fluences F_{NG}m out of the multiple second diffracted luminous fluxes becomes the processing threshold Fth,
control the adjustment mechanism when the fluence upper limit Fcr is greater than the fluence F_{OK}maxth of the first maximum diffracted luminous flux, which is provided when the fluence F_{NG}max of the second maximum diffracted luminous flux becomes the processing threshold Fth, by setting a target fluence F_{OK}mint, which is a target value of a fluence F_{OK}min of a first minimum diffracted luminous flux having a minimum of the fluences F_{OK}m out of the multiple first diffracted luminous fluxes, in such a way that the target fluence F_{OK}mint
is greater than a value as a result of addition of a first variation range indicating pulse energy variation δE of the pulse energy of the pulse laser light incident on the diffractive optical element to the processing threshold Fth,
is smaller than or equal to a value as a result of subtraction of a second variation range indicating the pulse energy variation δE from a value Fth/R_{N/O}, which is a result of division of the processing threshold Fth by an optical intensity ratio R_{N/O}, which is a result of division of an optical intensity I_{NG}max of the second maximum diffracted luminous flux by an optical intensity I_{OK}min of the first minimum diffracted luminous flux,
control the adjustment mechanism when the fluence upper limit Fcr is smaller than the fluence F_{OK}maxth of the first maximum diffracted luminous flux, which is provided when the fluence F_{NG}max of the second maximum diffracted luminous flux becomes the processing threshold Fth by setting the target fluence F_{OK}mint in such a way that
the target fluence F_{OK}mint is greater than a value as a result of addition of the first variation range to the processing threshold Fth, and
is smaller than or equal to a value as a result of subtraction of a third variation range indicating the pulse energy variation δE from a value Fcr/R_{O/O}, which is a result of division of the fluence upper limit Fcr by an optical intensity ratio R_{O/O}, which is a result of division of an optical intensity I_{OK}max of the first maximum diffracted luminous flux by the optical intensity I_{OK}min of the first minimum diffracted luminous flux.

16. A laser processing method comprising:
causing a laser apparatus to output pulse laser light;
causing a diffractive optical element to divide the pulse laser light into multiple first diffracted luminous fluxes radiated to multiple processing points on a workpiece, and multiple second diffracted luminous fluxes radiated to multiple non-processing points on the workpiece;
controlling an adjustment mechanism configured to adjust pulse energy of the pulse laser light based on parameters including a processing threshold Fth of a fluence for processing the workpiece in such a way that
a fluence F_{OK}m of the first diffracted luminous fluxes at a surface of the workpiece is greater than the processing threshold Fth, and
a fluence F_{NG}m of the second diffracted luminous fluxes at the surface of the workpiece is smaller than or equal to the processing threshold Fth; and
causing a focusing optical system to focus each of the first and second diffracted luminous fluxes at the workpiece.

17. The laser processing method according to claim 16, further comprising:
measuring an optical intensity I_{OK} of the first diffracted luminous fluxes at the surface of the workpiece, and an optical intensity I_{NG} of the second diffracted luminous fluxes at the surface of the workpiece; and
controlling the adjustment mechanism by setting a target fluence F_{OK}mt, which is a target value of the fluence F_{OK}m of the first diffracted luminous fluxes in such a way that
the target fluence F_{OK}mt is greater than the processing threshold Fth, and
the target fluence F_{OK}mt is smaller than or equal to a value Fth/R, which is a result of division of the processing threshold Fth by an optical intensity ratio R, which is a result of division of the optical intensity I_{NG} of the second diffracted luminous fluxes by the optical intensity I_{OK} of the first diffracted luminous fluxes.

18. The laser processing method according to claim 16, further comprising:
measuring an optical intensity I_{OK}min of a first minimum diffracted luminous flux having a minimum of the fluences F_{OK}m out of the multiple first diffracted luminous fluxes, and an optical intensity I_{NG}max of a second maximum diffracted luminous flux having a maximum of the fluences F_{NG}m out of the multiple second diffracted luminous fluxes; and
controlling the adjustment mechanism by setting a target fluence F_{OK}mint, which is a target value of a fluence F_{OK}min of the first minimum diffracted luminous flux in such a way that the target fluence F_{OK}mint
is greater than the processing threshold Fth, and
is smaller than or equal to a value Fth/R_{N/O}, which is a result of division of the processing threshold Fth by an optical intensity ratio R_{N/O}, which is a result of division of the optical intensity I_{NG}max of the second maximum diffracted luminous flux by the optical intensity I_{OK}min of the first minimum diffracted luminous flux.

19. The laser processing method according to claim 16, further comprising:
measuring an optical intensity I_{OK}min of a first minimum diffracted luminous flux having a minimum of the fluences F_{OK}m out of the multiple first diffracted luminous fluxes, an optical intensity I_{NG}max of a second maximum diffracted luminous flux having a maximum of the fluences F_{NG}m out of the multiple second diffracted luminous fluxes, and an optical intensity I_{OK}max of a first maximum diffracted luminous flux having a maximum of the fluences F_{OK}m out of the multiple first diffracted luminous fluxes; and
controlling the adjustment mechanism by setting a target fluence F_{OK}mint, which is a target value of a fluence F_{OK}min of the first minimum diffracted luminous flux in such a way that the target fluence F_{OK}mint
is greater than the processing threshold Fth,
is smaller than or equal to a value Fth/R_{N/O}, which is a result of division of the processing threshold Fth by an optical intensity ratio R_{N/O}, which is a result of division of the optical intensity I_{NG}max of the second maximum diffracted luminous flux by the optical intensity I_{OK}min of the first minimum diffracted luminous flux, and
is smaller than or equal to a value Fcr/R_{O/O}, which is a result of division of a fluence upper limit Fcr by an optical intensity ratio R_{O/O}, which is a result of division of the optical intensity I_{OK}max of the first maximum diffracted luminous flux by the optical intensity I_{OK}min of the first minimum diffracted luminous flux.

20. A method for manufacturing an electronic device, the method comprising:
processing an interposer substrate with laser light by using a laser processing system to produce an interposer;
coupling the interposer to an integrated circuit chip to electrically connect the interposer and the integrated circuit chip to each other; and
coupling the interposer to a circuit substrate to electrically connect the interposer and the circuit substrate to each other,
the laser processing system including
a laser apparatus configured to output pulse laser light,
a diffractive optical element configured to divide the pulse laser light into multiple first diffracted luminous fluxes radiated to multiple processing points on a workpiece, and multiple second diffracted luminous fluxes radiated to multiple non-processing points on the workpiece,
a focusing optical system configured to focus each of the first and second diffracted luminous fluxes at the workpiece;
an adjustment mechanism configured to adjust pulse energy of the pulse laser light incident on the diffractive optical element, and
a processor configured to control the adjustment mechanism based on parameters including a processing threshold Fth of a fluence for processing the workpiece in such a way that
a fluence F_{OK}m of the first diffracted luminous fluxes at a surface of the workpiece is greater than the processing threshold Fth, and
a fluence F_{NG}m of the second diffracted luminous fluxes at the surface of the workpiece is smaller than or equal to the processing threshold Fth.
